(19) United States
(12) Patent Application Publication
(10) Pub. No.: US 2025/0241166 A1
(43) Pub. Date: Jul. 24, 2025

(54) DISPLAY APPARATUS

(71) Applicant: Samsung Display Co., LTD., Yongin-si (KR)

(72) Inventors: Jinsu Lee, Yongin-si, (KR); Jihyun Kim, Yongin-si (KR); Haseok Jeon, Yongin-si (KR); Chanyoung Kim, Yongin-si (KR); Choongyoul Im, Yongin-si (KR); Seongmin Cho, Yongin-si (KR); Beohmrock Choi, Yongin-si (KR)

(21) Appl. No.: 18/766,789

(22) Filed: Jul. 9, 2024

(30) Foreign Application Priority Data
Jan. 24, 2024 (KR) 10-2024-0011176

(51) Int. Cl. H10K 59/38; H10K 59/122; H10K 59/80

(52) U.S. Cl. CPC H10K 59/38; H10K 59/122; H10K 59/8792

(57) ABSTRACT

A display apparatus, in which diffraction patterns observed on a screen are prevented or minimized, includes a color filter layer disposed on a plurality of light-emitting elements including a first color filter configured to transmit light in a first wavelength band, a second color filter configured to transmit light in a second wavelength band, and a third color filter configured to transmit light in a third wavelength band, where, in a plan view, the first to third color filters each have an elliptical shape and do not overlap each other.

This application claims priority to Korean Patent Application No. 10-2024-0011176, filed on Jan. 24, 2024, and all the benefits accruing therefrom under 35 U.S.C. § 119, the content of which in its entirety is herein incorporated by reference.

### BACKGROUND

### 1. Field

The invention relates to a display apparatus, and more particularly, to a display apparatus in which diffraction patterns observed on a screen are prevented or minimized.

### 2. Description of the Related Art

Display apparatuses are configured to receive information about images and display those images. Display apparatuses may be used as displays for small products such as mobile phones or large products such as televisions.

A display apparatus includes a plurality of pixels configured to receive electrical signals and emit light to display images to an outside observer. Each of the pixels include a light-emitting element. For example, an organic light-emitting display apparatus includes an organic light-emitting element as a light-emitting element. In general, an organic light-emitting display apparatus includes a thin-film transistor and an organic light-emitting element disposed on a substrate. The organic light-emitting element operates to emit light by itself.

### SUMMARY

One or more embodiments include a display apparatus in which diffraction patterns that are observed on a display screen are prevented or minimized.

Additional aspects will be set forth in part in the description which follows and, in part, will be apparent from the description, or may be learned by practice of the presented embodiments.

According to an embodiment, a display apparatus includes a substrate, a plurality of light-emitting elements disposed on the substrate, where the plurality of light-emitting elements include at least a first light-emitting element configured to generate light in a first wavelength band, a second light-emitting element configured to generate light in a second wavelength band, and a third light-emitting element configured to generate light in a third wavelength band, a pixel defining layer disposed on the substrate and arranged to be on a same layer as the plurality of light-emitting elements, where the pixel defining layer covers an edge of each of the plurality of light-emitting elements, a light blocking material layer disposed on the pixel defining layer, and a color filter layer disposed on the plurality of light-emitting elements and arranged to be on a same layer as the light blocking material layer, where the color filter layer includes a first color filter configured to transmit the light in the first wavelength band, a second color filter configured to transmit the light in the second wavelength band, and a third color filter configured to transmit the light in the third wavelength band, where, in a plan view, the first to third color filters each have an elliptical shape and do not overlap each other.

In an embodiment, the first to third color filters may be arranged to be on a same layer.

In an embodiment, a portion of the light blocking material layer may be exposed in an upward direction between the first to third color filters.

In an embodiment, the display apparatus may further include an overcoating layer disposed on the color filter layer and the light blocking material layer.

In an embodiment, a portion of the light blocking material layer may be in contact with a lower surface of the overcoating layer.

In an embodiment, the light blocking material layer may include a plurality of openings disposed on the plurality of light-emitting elements in a plan view.

In an embodiment, the plurality of openings may include a first opening in which the first color filter is arranged, a second opening in which the second color filter is arranged, and a third opening in which the third color filter is arranged.

In an embodiment, in a plan view, areas of the first to third openings may not match each other.

In an embodiment, in a plan view, diameters of the first to third openings may be different from each other.

In an embodiment, the first color filter may cover an inner surface of the first opening, the second color filter may cover an inner surface of the second opening, and the third color filter may cover an inner surface of the third opening.

In an embodiment, a distance between a central area of the first color filter and an upper surface of the substrate may be less than a distance between an upper surface of the light blocking material layer and the upper surface of the substrate.

In an embodiment, a distance between a central area of the second color filter and the upper surface of the substrate may be less than the distance between the upper surface of the light blocking material layer and the upper surface of the substrate.

In an embodiment, a central area of each of the first to third color filters may have a concavely recessed shape.

In an embodiment, in a plan view, the first color filter may have a first elliptical shape with a first major axis extending in a first direction. In a plan view, the second color filter may have a second elliptical shape with a second major axis extending in a second direction. In a plan view, the third color filter may have a third elliptical shape with a third major axis extending in a third direction.

In an embodiment, in a plan view, the first to third directions may be different from each other.

In an embodiment, in a plan view, eccentricities of the first to third elliptical shapes may be different from each other.

In an embodiment, in a plan view, areas of the first to third elliptical shapes may be different from each other.

In an embodiment, in a plan view, a ratio of an area of the first elliptical shape to an area of the second elliptical shape may be about 2:3.

In an embodiment, an eccentricity of the first elliptical shape and an eccentricity of the second elliptical shape may be between about 0.5 and about 0.8.

According to an embodiment, a display apparatus includes a substrate, a plurality of light-emitting elements disposed on the substrate, where the plurality of light-emitting elements include at least a first light-emitting element configured to generate light in a first wavelength band, a second light-emitting element configured to generate light in a second wavelength band, and a third light-emitting element configured to generate light in a third wavelength band, a pixel defining layer disposed on the substrate and arranged to be on a same layer as the plurality of light-emitting elements, where the pixel defining layer covers an edge of each of the plurality of light-emitting elements, a touch sensor layer disposed on the plurality of light-emitting elements and the pixel defining layer, where the touch sensor layer includes a touch conductive layer that overlaps the pixel defining layer in a plan view, and a color filter layer disposed on the touch sensor layer, where the color filter layer includes a first color filter configured to transmit the light in the first wavelength band, a second color filter configured to transmit the light in the second wavelength band, and a third color filter configured to transmit the light in the third wavelength band, where, in a plan view, an edge of the first color filter overlaps the touch conductive layer, and in a plan view, a central area of the first color filter overlaps the first light-emitting element, and in a plan view, a portion of the second color filter is disposed on the edge of the first color filter, and, in a plan view, a remaining portion of the second color filter overlaps the second light-emitting element.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating a display apparatus, according to an embodiment;

FIG. 2 is an equivalent circuit diagram schematically illustrating a pixel of the display apparatus of FIG. 1, according to an embodiment;

FIG. 3 is a cross-sectional view schematically illustrating a portion of the display apparatus of FIG. 1, according to an embodiment;

FIG. 4 is a cross-sectional view schematically illustrating an example of a portion of a display area of FIG. 1, according to an embodiment;

FIG. 5 is a cross-sectional view schematically illustrating an example of a portion of the display area of FIG. 1, according to an embodiment;

FIG. 6 is a cross-sectional view schematically illustrating an example of a portion of the display area of FIG. 1, according to an embodiment;

FIG. 7 is a plan view schematically illustrating an example of a color filter pattern arranged in an area A of FIG. 1, according to an embodiment;

FIG. 8 is a plan view schematically illustrating an example of a color filter pattern arranged in the area A of FIG. 1, according to an embodiment;

FIG. 9 is a plan view schematically illustrating an example of a color filter pattern arranged in the area A of FIG. 1, according to an embodiment;

FIG. 10 is a table comparing effects of examples of color filter patterns, according to an embodiment;

FIG. 11 is a cross-sectional view schematically illustrating a portion of a display area of a display apparatus, according to a comparative example;

FIG. 12 is a plan view schematically illustrating an example of a color filter pattern in a display area of a display apparatus, according to a comparative example;

FIG. 13 is a cross-sectional view schematically illustrating overlapping shapes of edges of color filters in a display apparatus, according to a comparative example;

FIG. 14 is a cross-sectional view schematically illustrating overlapping shapes of edges of color filters in a display apparatus, according to a comparative example;

FIG. 15 is a table showing result data obtained from a comparative experiment on a degree of diffraction according to a step between a color filter layer and a light blocking material layer;

FIG. 16 is a table showing result data obtained from a comparative experiment on a degree of diffraction according to pattern sizes of the color filter layer and the light blocking material layer;

FIG. 17 is a graph schematically showing a position at which a diffraction pattern appears, according to an embodiment;

FIG. 18 is a plan view illustrating a portion of a display apparatus, focusing on a color filter layer and a light blocking material layer, according to another embodiment;

FIG. 19 is a cross-sectional view of the display apparatus of FIG. 18 taken along line I-I′ of FIG. 18, according to an embodiment;

FIG. 20 is a cross-sectional view of the display apparatus of FIG. 18 taken along line II-II′ of FIG. 18, according to an embodiment;

FIG. 21 is a plan view illustrating a portion of a display apparatus, focusing on a color filter layer and a light blocking material layer, according to another embodiment;

FIG. 22 is a cross-sectional view of the display apparatus of FIG. 21 taken along line Ill-III′ of FIG. 21, according to an embodiment;

FIG. 23 is a cross-sectional view of the display apparatus of FIG. 21 taken along line IV-IV′ of FIG. 21, according to an embodiment;

FIG. 24 is a plan view illustrating a portion of a display apparatus, focusing on a color filter layer and a light blocking material layer, according to another embodiment;

FIG. 25 is a cross-sectional view of the display apparatus of FIG. 24 taken along line V-V′ of FIG. 24, according to an embodiment;

FIG. 26 is a cross-sectional view of the display apparatus of FIG. 24 taken along line VI-VI′ of FIG. 24, according to an embodiment;

FIG. 27 is a plan view illustrating a portion of a display apparatus, focusing on a color filter layer and a light blocking material layer, according to another embodiment;

FIG. 28 is a cross-sectional view of the display apparatus of FIG. 27 taken along line VII-VII′ of FIG. 27, according to an embodiment; and

FIG. 29 is a cross-sectional view of the display apparatus of FIG. 27 taken along line VIII-VIII′ of FIG. 27, according to an embodiment.

### DETAILED DESCRIPTION

Reference will now be made in detail to embodiments of the invention, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the invention allows for various changes and numerous embodiments, certain embodiments will be illustrated in the drawings and described in detail in the written description. Effects and features of the invention, and methods of achieving them will be clarified with reference to embodiments described below in detail with reference to the drawings. However, the invention is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

It will be understood that, when a layer, film, region, or plate is referred to as being “on” another element, the layer, film, region, or plate may be “directly on” the other element, and intervening elements may be present therebetween. In addition, It will be understood that, when a layer, film, region, or plate is referred to as being “below” another element, the layer, film, region, or plate may be “directly below” the other element, and intervening elements may be present therebetween.

Also, sizes of elements in the drawings may be exaggerated or reduced for convenience of explanation. For example, because sizes and thicknesses of elements in the drawings are arbitrarily illustrated for convenience of explanation, the invention is not limited thereto. That is, for convenience of explanation, the size, thickness, and ratio of elements illustrated in the drawings may be exaggerated and/or simplified for clarity. Accordingly, spatially relative terms such as “below,” “under,” “lower,” “above,” “upper,” etc. are terms used herein to easily describe a relationship of one element or feature.

Terms used to describe space, direction, etc. in the present specification are terms for describing the space and direction illustrated in the drawings, but may be understood as terms for describing various other directions or various viewpoints. For example, when a device or element illustrated in the drawings is turned over, the device or element described as “below” may be interpreted in a different direction (e.g., rotated 90 degrees, an opposite direction, etc.). For example, when a device or element illustrated in the drawings is turned over, the device or element described as “on” may be interpreted as a different direction (e.g., rotated 90 degrees, an opposite direction, etc.). Accordingly, “below” and “on” may include both upward and downward directions. In addition, a device or element may be oriented differently from the drawings, and the description of space or direction described herein may be variously interpreted.

The order of processes or the order of methods understood in the description of processes, manufacturing methods, etc. in the present specification may be different from the stated order. For example, two consecutively described processes or methods may be performed simultaneously or substantially simultaneously or may be performed in the order opposite to the described order.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

It will be understood that the terms “first,” “second,” “third,” etc. may be used herein to describe specific elements, and the terms “first,” “second,” “third,” etc. may be only used to distinguish one element from another.

It will be understood that when an element is referred to as being “connected to” or “coupled to” another element, the element may be directly or indirectly connected to or combined with the other element.

Similarly, it will be understood that when an element is referred to as being “electrically connected to” another element, the element may be directly or indirectly electrically connected to the other element or may be directly or indirectly electrically connected to the other element through a conductive element.

In addition, it will be understood that when an element is referred to as being “between” two elements, the element may be understood as being the only element arranged between two elements, or elements other than the element may be arranged between the two elements.

The terms as used in the present specification are only used to describe specific embodiments and are not intended to limit the invention. The singular forms “a” and “an” as used herein are intended to include the plural forms as well unless the context clearly indicates otherwise.

For example, the expressions “mixing,” “mixture,” “mix,” “have,” etc. specify the presence of the stated features, integers, steps, operations, elements, and/or components, but do not exclude the presence or addition of one or more other features, integers, steps, operations, elements, components, and/or groups.

For example, the term “and/or” includes any and all combinations of one or more of the associated listed items. For example, the expression “A and/or B” indicates only A, only B, or both A and B. The expressions such as “at least one” may be used to indicate one or more elements among a plurality of elements. For example, the expressions “at least one of a, b, or c” and “at least one selected from a, b, and c” may indicate “only a,” “only b,” “only c,” “a and b,” “b and c,” “a and c,” or “all of a, b, and c.”

For example, “substantially,” “about,” and terms similar thereto are used as terms of approximation rather than terms of degree, and may be terms used to describe inherent fluctuations in measured or calculated values that may be recognized by those of ordinary skill in the art. For example, terms such as “be able to,” “may,” etc. may be used to mean “one or more embodiments disclosed herein.”

For example, in the present specification, the expression “one layer has the same layer structure as another layer” may mean that a plurality of layers included in one layer may be included in the other layer in the same order. For example, a plurality of layers included in one layer and a plurality of layers included in another layer may each include the same material and may be formed in the same order.

Electronic or electrical devices and/or any other related devices or components (e.g., some of various modules) according to embodiments described herein may be implemented by using any suitable hardware, firmware (e.g., an application-specific integrated circuit), or a combination of software, firmware, and hardware. For example, the various components of these devices may be formed on one integrated circuit (IC) chip or on separate IC chips. Moreover, the various components of these devices may be formed on a flexible printed circuit film, a tape carrier package (TCP), a printed circuit board (PCB), or a single substrate. In addition, the various components of these devices may be processes or threads, may be executed on one or more processors, may execute computer program instructions on one or more computing devices, and may interact with other system components to perform various functions described herein.

The computer program instructions are stored in a memory that may be implemented in a computing device by using a standard memory device, such as random access memory (RAM). The computer program instructions may also be stored on, for example, other non-transitory computer-readable media, such as a compact disc read-only memory (CD-ROM) or flash drive. Furthermore, it will be understood by those of ordinary skill in the art that the functions of various computing devices may be combined or integrated into a single computing device, or the functions of particular computing devices may be distributed over one or more other computing devices without departing from the spirit and scope of the embodiments.

Hereinafter, a display apparatus, according to an embodiment, will be described in detail herein.

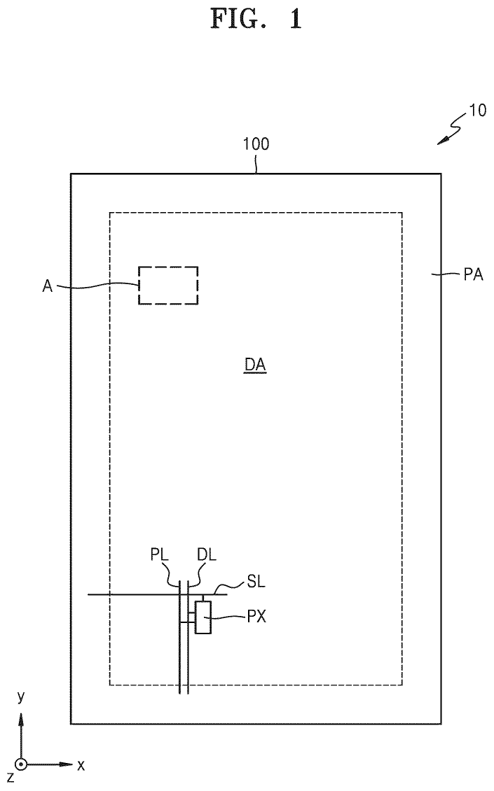

FIG. 1 is a plan view schematically illustrating a display apparatus, according to an embodiment.

As illustrated in FIG. 1, the display apparatus, according to an embodiment, may include a display panel 10. The invention may be applied to any types of display apparatus as long as the display apparatus includes the display panel 10. Examples of the display apparatus may include various devices, such as smartphones, tablets, laptops, televisions, or billboards. The display apparatus, according to an embodiment, may include thin-film transistors and capacitors. The thin-film transistors and the capacitors may be implemented by conductive layers and insulating layers.

In an embodiment, the display panel 10 may include a display area DA and a peripheral area PA disposed outside of the display area DA. Although FIG. 1 illustrates that the display area DA has a rectangular shape, the invention is not limited thereto. Accordingly, in another embodiment, the display area DA may have various shapes, for example, a circular shape, an elliptical shape, a polygonal shape, or a specific figure shape.

In an embodiment, the display area DA enables an image to be displayed, and a plurality of pixels PX may be arranged in the display area DA. Each of the pixels PX may include a display element, such as an organic light-emitting element. The pixels PX may be configured to externally emit, for example, red light, green light, or blue light. The pixel PX may be connected to a pixel circuit including a thin-film transistor (TFT), a storage capacitor, and the like. The pixel circuit may be connected to a scan line SL which is configured to transmit a scan signal, a data line DL crossing the scan line SL and which is configured to transmit a data signal, and a driving voltage line PL crossing the scan line SL and which is configured to supply a driving voltage. The data line DL and the driving voltage line PL may extend in a y direction (hereinafter referred to as a first direction), and the scan line SL may extend in an x direction (hereinafter referred to as a second direction).

In an embodiment, the pixel PX may be configured to externally emit light having a luminance corresponding to an electrical signal that is output from the pixel circuit electrically connected thereto. The display area DA may enable a certain image to be displayed by light emitted from the pixel PX. The pixel PX as used herein may be defined as an emission area configured to emit one of red light, green light, and blue light.

In an embodiment, the peripheral area PA may be an area in which pixels PX are not arranged, and thus, an image is not displayed. Power supply lines for driving the pixels PX may be arranged in the peripheral area PA. In addition, pads may be arranged in the peripheral area PA. The pads and integrated circuit (IC) devices, such as a printed circuit board or a driver IC including a driving circuit may be electrically connected to each other in the peripheral area PA.

For reference, because the display panel 10 includes a substrate 100, it may be stated that the substrate 100 has the display area DA and the peripheral area PA. Details of the substrate 100 will be described below.

In an embodiment, a plurality of transistors may be arranged in the display area DA, wherein a first terminal of the transistor may be a source electrode or a drain electrode and a second terminal of the transistor may be an electrode different from the first terminal, according to the type (N-type or P-type) of transistor and/or operating conditions. For example, when the first terminal is a source electrode, the second terminal may be a drain electrode.

In an embodiment, the transistors may include a driving transistor, a data write transistor, a compensation transistor, an initialization transistor, an emission control transistor, and the like. The driving transistor may be connected between the driving voltage line PL and an organic light-emitting element, and the data write transistor may be connected to the data line DL and the driving transistor and configured to perform a switching operation of transmitting a data signal transferred to the data line DL.

The compensation transistor may be configured to be turned on in response to a scan signal received through the scan line SL and may compensate for a threshold voltage of the driving transistor by connecting the driving transistor to the organic light-emitting element.

The initialization transistor may be configured to be turned on in response to the scan signal received through the scan line SL and may initialize a gate electrode of the driving transistor by transmitting an initialization voltage to the gate electrode of the driving transistor. The scan line connected to the initialization transistor may be a separate scan line that is different from the scan line connected to the compensation transistor.

The emission control transistor may be configured to be turned on in response to an emission control signal received through an emission control line. As a result, a driving current may flow through the organic light-emitting element.

In an embodiment, the organic light-emitting element may include a pixel electrode (an anode) and an opposite electrode (a cathode) and may be configured to receive a necessary voltage from the pixel electrode (the anode) and the opposite electrode (the cathode). The organic light-emitting element may be configured to display an image by emitting light according to the driving current received from the driving transistor.

Hereinafter, an organic light-emitting display will be described as an example of the display apparatus, according to an embodiment, but the display apparatus is not limited thereto. In another embodiment, examples of the display apparatus may include an inorganic light-emitting display (or an inorganic electroluminescence (EL) display), a quantum dot light-emitting display, and the like. For example, an emission layer of a display element included in the display apparatus may include an organic material or an inorganic material. Also, the display apparatus may include an emission layer and quantum dots located on a path of light emitted from the emission layer.

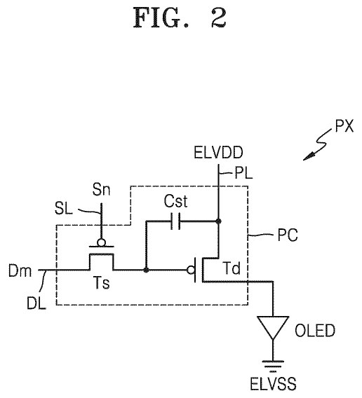

FIG. 2 is an equivalent circuit diagram schematically illustrating the pixel PX of the display apparatus of FIG. 1, according to an embodiment.

In an embodiment and as illustrated in FIG. 2, the pixel PX may include a pixel circuit PC connected to a scan line SL and a data line DL, and an organic light-emitting element OLED connected to the pixel circuit PC.

In an embodiment, the pixel circuit PC may include a driving thin-film transistor Td, a switching thin-film transistor Ts, like a storage capacitor Cst. The switching thin-film transistor Ts may be connected to the scan line SL and the data line DL and may be configured to transmit, to the driving thin-film transistor Td, a data signal Dm which is input through the data line DL in response to a scan signal Sn which is input through the scan line SL.

The storage capacitor Cst may be connected to the switching thin-film transistor Ts and a driving voltage line PL and may be configured to store a voltage corresponding to a difference between a voltage received from the switching thin-film transistor Ts and a first power supply voltage (or a driving voltage) ELVDD which is supplied to the driving voltage line PL.

The driving thin-film transistor Td may be connected to the driving voltage line PL and the storage capacitor Cst and may be configured to control a driving current flowing from the driving voltage line PL to the organic light-emitting element OLED according to a voltage value which may be stored in the storage capacitor Cst. The organic light-emitting element OLED may be configured to emit light having a certain luminance according to the driving current.

The organic light-emitting element OLED may be configured to receive a second power supply voltage (a common voltage) ELVSS. For example, the organic light-emitting element OLED may be configured to receive the second power supply voltage (the common voltage) ELVSS through an opposite electrode (a cathode), and the organic light-emitting element OLED may be configured to emit light having a certain luminance responsive to the driving current according to the voltage difference between the first power supply voltage (the driving voltage) ELVDD and the second power supply voltage (the common voltage) ELVSS.

Although FIG. 2 illustrates that the pixel circuit PC includes two thin-film transistors and one storage capacitor, the invention is not limited thereto. For example, in another embodiment, the pixel circuit PC may include two or more storage capacitors and/or may include three or more thin-film transistors.

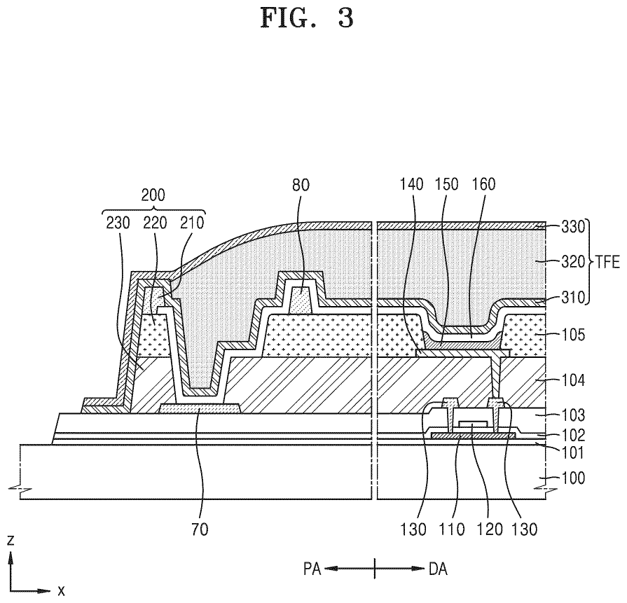

FIG. 3 is a cross-sectional view schematically illustrating a portion of the display apparatus of FIG. 1, according to an embodiment.

In an embodiment, the substrate 100 may include areas corresponding to the display area DA and the peripheral area PA which is disposed outside of the display area DA. The substrate 100 may include various flexible or bendable materials. For example, in an embodiment, the substrate 100 may include glass, metal, or polymer resin. In addition, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. In other embodiments, other modifications are possible. For example, in another embodiment, the substrate 100 may have a multilayer structure that includes two layers and a barrier layer disposed therebetween, wherein the two layers may include polymer resin and the barrier layer may include an inorganic material (e.g., silicon oxide, silicon nitride, silicon oxynitride, etc.)

In an embodiment, a buffer layer 101 may be disposed on the substrate 100, where the buffer layer 101 may act as a barrier layer and/or a blocking layer that prevents impurity ions from diffusing, prevents infiltration of moisture or ambient air, and performs surface planarization. The buffer layer 101 may include silicon oxide, silicon nitride, or silicon oxynitride. Also, the buffer layer 101 may control the rate of heat supply during a crystallization process for forming a semiconductor layer 110 so that the semiconductor layer 110 is uniformly crystallized.

The semiconductor layer 110 may be disposed on the buffer layer 101, where the semiconductor layer 110 may include polysilicon. The semiconductor layer 110 may include a channel region undoped with impurities, and a source region and a drain region formed by doping impurities into both sides of the channel region. The impurities may vary depending on the type of the thin-film transistor and may be an N-type impurity or a P-type impurity. Although not illustrated, the display apparatus, according to another embodiment, may further include another semiconductor layer disposed on another layer.

In an embodiment, a gate insulating layer 102 may be disposed on the semiconductor layer 110, where the gate insulating layer 102 may be configured to secure insulation between the semiconductor layer 110 and a gate layer 120. The gate insulating layer 102 may include an inorganic material, such as silicon oxide, silicon nitride, and/or silicon oxynitride, and may be between the semiconductor layer 110 and the gate layer 120. In addition, the gate insulating layer 102 may have a shape corresponding to the entire surface of the substrate 100 and may have a structure in which contact holes are formed in preset portions. The gate insulating layer 102, including the inorganic material, may be formed by chemical vapor deposition (CVD) or atomic layer deposition (ALD). The same applies to embodiments and modifications to be described below.

The gate layer 120 may be disposed on the gate insulating layer 102, where the gate layer 120 may be disposed at a position vertically overlapping the semiconductor layer 110 and which may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), titanium (Ti), tungsten (W), and copper (Cu). Details of the gate layer 120 are described below. Although not illustrated, the display apparatus, according to another embodiment, may further include another gate layer disposed on another layer.

In an embodiment, an interlayer insulating layer 103 may be disposed on the gate layer 120, where the interlayer insulating layer 103 may cover the gate layer 120. The interlayer insulating layer 103 may include an inorganic material. For example, the interlayer insulating layer 103 may include metal oxide or metal nitride. Specifically, in an embodiment, the interlayer insulating layer 103 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In another embodiment, the interlayer insulating layer 103 may have a dual structure of SiOₓ/SiN_{y} or SiNₓ/SiO_{y}.

In an embodiment, a conductive layer 130 may be disposed on the interlayer insulating layer 103, where the conductive layer 130 may act as an electrode connected to the source/drain region of the semiconductor layer through a through-hole which is included in the interlayer insulating layer 103.

The conductive layer 130 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer, and/or a Cu layer. For example, the conductive layer 130 may include a Ti/Al/Ti structure.

Although not illustrated, the display apparatus, according to an embodiment, may further include another conductive layer disposed on another layer, where the other conductive layer may be, for example, a wiring layer that functions as a wiring. The other conductive layer may include the same material as that of the conductive layer 130 and may have the same layer structure as that of the conductive layer 130.

In an embodiment, an organic insulating layer 104 may be disposed on the conductive layer 130, where the organic insulating layer 104 may be an organic insulating layer acting as a planarization layer because the organic insulating layer 104 covers the upper portion of the conductive layer 130 and has a substantially flat upper surface. The organic insulating layer 104 may include, for example, an organic material, such as acrylic, benzocyclobutene (BCB), or hexamethyldisiloxane (HMDSO). The organic insulating layer 104 may be variously modified. For example, in another embodiment, the organic insulating layer 104 may include a single layer or layers.

Although not illustrated, the display apparatus, according to an embodiment, may further include another organic insulating layer disposed on another layer. The other organic insulating layer may be disposed on the other conductive layer described above and may act as a planarization layer by covering the upper portion of the other conductive layer. The other organic insulating layer may include the same material as that of the organic insulating layer 104 and may have the same layer structure as that of the organic insulating layer 104.

In an embodiment, a pixel electrode 140 may be disposed on the organic insulating layer 104. In another embodiment, the pixel electrode 140 may be disposed on the other organic insulating layer described above. However, for convenience of explanation, it is assumed that the pixel electrode 140 is disposed on the organic insulating layer 104.

In an embodiment, the pixel electrode 140 may be connected to the conductive layer 130 through a contact hole formed in the organic insulating layer 104. A display element may be disposed on the pixel electrode 140 and an organic light-emitting element OLED may be used as the display element. That is, the organic light-emitting element OLED may be disposed on, for example, the pixel electrode 140. The pixel electrode 140 may include a transmissive conductive layer and/or a reflective layer. The transmissive conductive layer may include a transmissive conductive oxide, such as indium tin oxide (ITO), In₂O₃, or indium zinc oxide (IZO), and the reflective layer may include metal, such as Al or Ag. For example, the pixel electrode 140 may have a three-layer structure of ITO/Ag/ITO.

In an embodiment, a pixel defining layer 105 may be disposed on the organic insulating layer 104 to cover the edge of the pixel electrode 140. For example, the pixel defining layer 105 may cover the edge of the pixel electrode 140. The pixel defining layer 105 may have a pixel opening corresponding to a pixel. The pixel opening may be formed to expose at least the central portion of the pixel electrode 140. The pixel opening may be defined by the pixel defining layer 105.

In an embodiment, the pixel defining layer 105 may include, for example, an organic material, such as polyimide or HMDSO. In addition, a spacer 80 may be disposed on the pixel defining layer 105. It should be appreciated that although the spacer 80 is illustrated as being arranged in the peripheral area PA, the spacer 80 may also be arranged in the display area DA. The spacer 80 may prevent the organic light-emitting element OLED from being damaged by sagging of a mask during a manufacturing process using a mask. The spacer 80 may include an organic insulating material and may include a single layer or layers.

In an embodiment, an intermediate layer 150 and an opposite electrode 160 may be disposed on the pixel opening described above. The intermediate layer 150 may include a low molecular weight material or a high molecular weight material. When the intermediate layer 150 includes a low molecular weight material, the intermediate layer 150 may include a hole injection layer, a hole transport layer, an emission layer, an electron transport layer, and/or an electron injection layer. When the intermediate layer 150 includes a high molecular weight material, the intermediate layer 150 may have a structure including a hole transport layer and an emission layer.

In an embodiment, the structure of the intermediate layer 150 is not limited thereto and may have various structures. For example, in an embodiment, at least one of the layers constituting the intermediate layer 150 may be integrally formed as a single body like the opposite electrode 160. In another embodiment, the intermediate layer 150 may have a layer patterned to correspond to each of the pixel electrodes 140.

In an embodiment, the opposite electrode 160 may include a transmissive conductive layer including a transmissive conductive oxide, such as ITO, In₂O₃, or IZO. The pixel electrode 140 may be used as an anode and the opposite electrode 160 may be used as a cathode. In other embodiments, the polarities of the pixel electrode 140 and the opposite electrode 160 may be reversed.

In an embodiment, the opposite electrode 160 may be disposed above the display area DA, and the display area DA may be arranged on the front. That is, the opposite electrode 160 may be integrally formed as a single body to cover the pixels. The opposite electrode 160 may be in electrical contact with a common power supply line 70 arranged in the peripheral area PA. For example, the opposite electrode 160 may extend to a barrier wall 200.

In an embodiment, t thin-film encapsulation layer TFE may completely cover the display area DA and may extend toward the peripheral area PA to cover at least a portion of the peripheral area PA. The thin-film encapsulation layer TFE may include a first inorganic encapsulation layer 310, a second inorganic encapsulation layer 330, and an organic encapsulation layer 320 disposed therebetween. The first inorganic encapsulation layer 310 and the second inorganic encapsulation layer 330 may each include at least one inorganic material selected from aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or layers including the inorganic material described above. The first inorganic encapsulation layer 310 and the second inorganic encapsulation layer 330 may include the same material as each other or may include different materials from each other.

In an embodiment, the thickness of the first inorganic encapsulation layer 310 may be different from the thickness of the second inorganic encapsulation layer 330. In another embodiment, the thickness of the second inorganic encapsulation layer 330 may be greater than the thickness of the first inorganic encapsulation layer 310, or the thicknesses of the first inorganic encapsulation layer 310 may be equal to the thickness of the second inorganic encapsulation layer 330.

In an embodiment, the organic encapsulation layer 320 may include a monomer-based material or a polymer-based material, where the polymer-based material may include acrylic resin, epoxy-based resin, polyimide, polyethylene, and the like. For example, the organic encapsulation layer 320 may include acrylate.

In an embodiment, the barrier wall 200 may be disposed on the peripheral area PA of the substrate 100. For example, the barrier wall 200 may include a portion 230 of the organic insulating layer 104, a portion 220 of the pixel defining layer 105, and a portion 210 of the spacer 80, but the invention is not limited thereto. In other embodiments, the barrier wall 200 may include at least one of the portion 230 of the organic insulating layer 104, the portion 220 of the pixel defining layer 105, or the portion 210 of the spacer 80.

In an embodiment, the barrier wall 200 may surround the display area DA and may prevent the organic encapsulation layer 320 of the thin-film encapsulation layer TFE from overflowing to the outside of the substrate 100. Accordingly, the organic encapsulation layer 320 may be in contact with the inner surface of the barrier wall 200 which is facing the display area DA. At this time, it will be understood that the expression “the organic encapsulation layer 320 is in contact with the inner surface of the barrier wall 200” may mean that the first inorganic encapsulation layer 310 is disposed between the organic encapsulation layer 320 and the barrier wall 200 and the organic encapsulation layer 320 is in contact with the first inorganic encapsulation layer 310. The first inorganic encapsulation layer 310 and the second inorganic encapsulation layer 330 may be disposed on the barrier wall 200 and may extend toward the edge of the substrate 100.

According to another embodiment, the thin-film encapsulation layer TFE may be replaced with a cover member that covers the entire display area DA. The cover member may be disposed to cover not only the display area DA but also to cover at least a portion of the peripheral area PA. The cover member may include a rigid member (e.g., glass, etc.). When the thin-film encapsulation layer TFE is replaced with the cover member, the barrier wall 200 may be omitted. In other embodiments, a transparent filler may be disposed between the cover member and the opposite electrode 160.

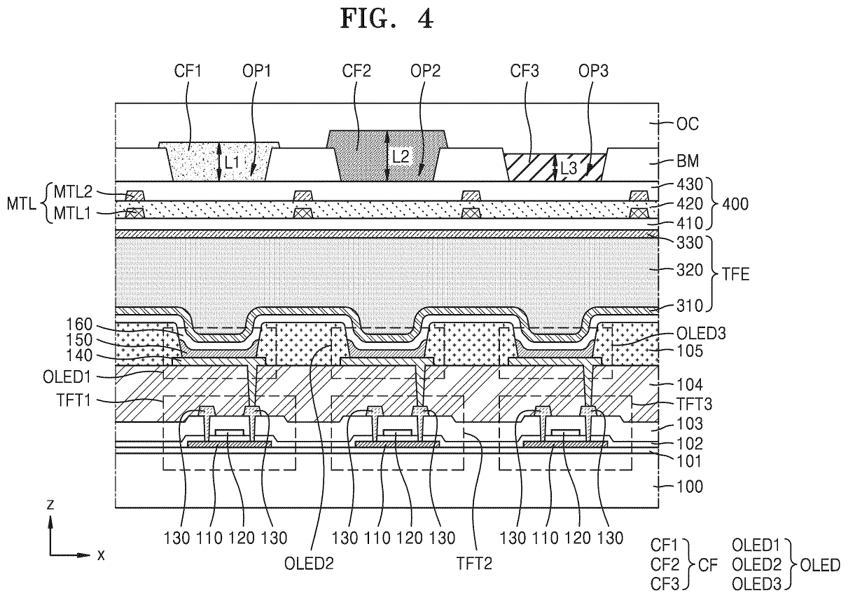

FIG. 4 is a cross-sectional view schematically illustrating an example of a portion of the display area of FIG. 1, according to an embodiment. In the following description of FIG. 4, the same or redundant description as provided above may be omitted.

In an embodiment and as illustrated in FIG. 4, a plurality of thin-film transistors may be disposed on a substrate, where each of the thin-film transistors may include a semiconductor layer 110 (e.g., a source region, a drain region, and a channel region of the semiconductor layer 110), a gate layer 120, and a conductive layer 130 connected to the semiconductor layer 110.

In an embodiment, the thin-film transistors may include at least a first thin-film transistor TFT1 configured to control a first light-emitting element OLED1 that generates light in a first wavelength band, a second thin-film transistor TFT2 configured to control a second light-emitting element OLED2 that generates light in the second wavelength band, and a third thin-film transistor TFT3 configured to control a third light-emitting element OLED3 that generates light in the third wavelength band. For example, the first thin-film transistor TFT1 may be disposed below the first light-emitting element OLED1, the second thin-film transistor TFT2 may be disposed below the second light-emitting element OLED2, and the third thin-film transistor TFT3 may be disposed below the third light-emitting element OLED3. The respective organic light-emitting element may be controlled by other thin-film transistors (not shown).

In an embodiment and as illustrated in FIG. 4, a touch sensor layer 400 may be disposed on a thin-film encapsulation layer TFE. The touch sensor layer 400 be included and may have a multilayer structure. The touch sensor layer 400 may include a first touch insulating layer 410, a first touch conductive layer MTL1, a second touch insulating layer 420, a second touch conductive layer MTL2, and a third touch insulating layer 430.

The first touch insulating layer 410 may be disposed on the thin-film encapsulation layer TFE and may include an inorganic material or an organic material and may include a single layer or layers. The first touch insulating layer 410 may prevent damage to the thin-film encapsulation layer TFE and may block interference signals that may occur when the touch sensor layer 400 is driven.

The first touch conductive layer MTL1 may be disposed on the first touch insulating layer 410, where the first touch conductive layer MTL1 may include a metal material layer and/or a transparent conductive layer. For example, the metal material layer may include at least one of molybdenum (Mo), silver (Ag), titanium (Ti), copper (Cu), aluminum (Al), or any alloy thereof. For example, the transparent conductive layer may include a transparent conductive oxide, such as indium tin oxide (ITO), indium zinc oxide (IZO), zinc oxide (ZnO), or indium tin zinc oxide (ITZO). The first touch conductive layer MTL1 may have a single-layer structure or a multilayer structure. For example, the multilayer structure may have a Ti/Al/Ti structure.

The second touch insulating layer 420 may be disposed on the first touch insulating layer 410. The second touch insulating layer 420 may be disposed on the first touch conductive layer MTL1. The second touch insulating layer 420 may cover the first touch conductive layer MTL1. The second touch insulating layer 420 may include an inorganic material or an organic material and may include a single layer or layers.

The second touch conductive layer MTL2 may be disposed on the second touch insulating layer 420 and may include a metal material layer and/or a transparent conductive layer. For example, the metal material layer may include at least one of molybdenum (Mo), silver (Ag), titanium (Ti), copper (Cu), aluminum (Al), or any alloy thereof. For example, the transparent conductive layer may include a transparent conductive oxide, such as indium tin oxide (ITO), indium zinc oxide (IZO), zinc oxide (ZnO), or indium tin zinc oxide (ITZO). The second touch conductive layer MTL2 may have a single-layer structure or a multilayer structure. For example, the multilayer structure may have a Ti/Al/Ti structure.

A touch conductive layer MTL may include the first touch conductive layer MTL1 and the second touch conductive layer MTL2.

The third touch insulating layer 430 may be disposed on the second touch insulating layer 420. The third touch insulating layer 430 may also be disposed on the second touch conductive layer MTL2, where the third touch insulating layer 430 may cover the second touch conductive layer MTL2. The third touch insulating layer 430 may include an inorganic material or an organic material and may include a single layer or layers.

For example, in an embodiment, the inorganic material included in each of the first to third touch insulating layers 410 to 430, respectively, may include at least one of silicon nitride (SiNₓ), aluminum nitride (AlN), zirconium nitride (ZrN), titanium nitride (TiN), hafnium nitride (HfN), tantalum nitride (TaN), silicon oxide (SiOₓ), aluminum oxide (Al₂O₃), titanium oxide (TiO₂), tin oxide (SnO₂), cerium oxide (CeO₂), or silicon oxynitride (SiON).

For example, in an embodiment, the organic material included in each of the first to third touch insulating layers 410 to 430, respectively, may include at least one of acrylic resin, methacrylic resin, polyisoprene, vinyl-based resin, epoxy-based resin, urethane-based resin, cellulose-based resin, or perylene-based resin.

In an embodiment and as illustrated in FIG. 4, a color filter layer CF and a light blocking material layer BM may be disposed on the touch sensor layer 400. In some embodiments, the touch sensor layer 400 may be omitted. When the touch sensor layer 400 is omitted, the color filter layer CF and the light blocking material layer BM may be disposed on the thin-film encapsulation layer TFE. For example, in an embodiment, the color filter layer CF and the light blocking material layer BM are disposed on a pixel defining layer 105. For example, in another embodiment, the color filter layer CF and the light blocking material layer BM may be disposed on a plurality of light-emitting elements.

In an embodiment, the color filter layer CF and the light blocking material layer BM may be elements that replace a polarizing film layer (not shown) used in an organic light-emitting display, where the color filter layer CF may selectively transmit light in a specific wavelength band and the light blocking material layer BM may block light generated from an organic light-emitting element OLED or prevent external light from being reflected to a display panel (see element 10 of FIG. 1). As a result, the color filter layer CF and the light blocking material layer BM may solve the problem of image quality deterioration that occurs due to the reflection of external light, which is the role of the polarizing film layer (not shown).

In an embodiment, the color filter layer CF may include a first color filter CF1 that transmits light in a first wavelength band, a second color filter CF2 that transmits light in a second wavelength band, and a third color filter CF3 that transmits light in a third wavelength band. For example, the first wavelength band may be a wavelength band corresponding to a blue color in the visible light region, the second wavelength band may be a wavelength band corresponding to a green color in the visible light region, and the third wavelength band may be a wavelength band corresponding to a red color in the visible light region. Additionally, the color filters CF1 to CF3 may be arranged to be on the same layer.

In an embodiment, the light blocking material layer BM may be a black matrix and may include various materials capable of absorbing at least a portion of light. For example, the light blocking material layer BM may include at least one of carbon black, graphite, a chromium-based material, dye, a metal reflective layer, or a light absorbing layer. The light blocking material layer BM may block or prevent the reflection of external light and may also prevent the internal reflection of light generated from the light-emitting element.

In an embodiment, the light blocking material layer BM may be disposed on the pixel defining layer 105. The light blocking material layer BM may not be disposed on a pixel opening exposing a pixel electrode 140.

In a plan view, the light blocking material layer BM may not overlap the pixel opening included in the pixel defining layer 105. In a plan view, the light blocking material layer BM may overlap the pixel defining layer 105 or may overlap a spacer disposed on the pixel defining layer 105. Also, in a plan view, when the light blocking material layer BM is located adjacent to the pixel opening included in the pixel defining layer 105, the light blocking material layer BM may block a portion of light (e.g., internal light) generated from the organic light-emitting element OLED, which may cause deterioration in image quality of the display apparatus.

Moreover, the light blocking material layer BM may include a plurality of openings. For example, in a plan view, the light blocking material layer BM may include a plurality of openings (e.g., a first opening OP1, a second opening OP2, and a third opening OP3) respectively disposed on the light-emitting elements (e.g., the first light-emitting element OLED1, the second light-emitting element OLED2, and the third light-emitting element OLED3).

In an embodiment, the light blocking material layer BM may include at least the first opening OP1, the second opening OP2, and the third opening OP3. The first opening OP1 may be disposed on the first light-emitting element OLED1, and the first color filter CF1 may be arranged in the first opening OP1. The second opening OP2 may be disposed on the second light-emitting element OLED2, and the second color filter CF2 may be arranged the second opening OP2. The third opening OP3 may be disposed on the third light-emitting element OLED3, and the third color filter CF3 may be arranged in the third opening OP3.

For example, the openings may include the first opening OP1 in which the first color filter CF1 is arranged, the second opening OP2 in which the second color filter CF2 is arranged, and the third opening OP3 in which the third color filter CF3 is arranged. For example, the first color filter CF1 may cover the inner surface of the first opening OP1, the second color filter CF2 may cover the inner surface of the second opening OP2, and the third color filter CF3 may cover the inner surface of the third opening OP3.

The openings may be formed in the light blocking material layer BM by an etching process using a mask and may be formed along a pattern of a preset shape. The color filter layer CF may be formed after the light blocking material layer BM is formed. The color filter layer CF may be arranged in the openings of the light blocking material layer BM. As the color filter layer CF is arranged in the openings of the light blocking material layer BM, the color filters CF1 to CF3 may be arranged to be disposed on the same layer.

In an embodiment and as illustrated in FIG. 4, the light-emitting elements may be respectively disposed on the thin-film transistors. The light-emitting elements may include the first light-emitting element OLED1 configured to generate light in the first wavelength band, the second light-emitting element OLED2 configured to generate light in the second wavelength band, and the third light-emitting element OLED3 configured to generate light in the third wavelength band.

For example, the first light-emitting element OLED1 may be disposed on the first thin-film transistor TFT1 to be disposed below the first color filter CF1. The second light-emitting element OLED2 may be disposed on the second thin-film transistor TFT2 to be disposed below the second color filter CF2. The third light-emitting element OLED3 may be disposed on the third thin-film transistor TFT3 to be disposed below the third color filter CF3.

For example, the first color filter CF1 may have a first thickness L1, the second color filter CF2 may have a second thickness L2, and the third color filter CF3 may have a third thickness L3, where the thicknesses L1 to L3 may respectively have sizes corresponding to the wavelength bands of light transmitted by the color filters. For reference, the thickness as used herein may refer to an average thickness or a thickness of a central area.

For example, in an embodiment, the second thickness L2 may be the largest among the thicknesses L1 to L3, where the second color filter CF2 may be configured to transmit green light and where the second thickness L2 may be about 3.2 μm.

For example, in an embodiment, the third thickness L3 may be the smallest among the thicknesses L1 to L3, where the third color filter CF3 may be configured to transmit blue light and where the third thickness L3 may be about 2.4 μm.

For example, in an embodiment, the first thickness L1 may be larger than the third thickness L3 and smaller than the second thickness L2, where the first color filter CF1 may be configured to transmit red light and where the first thickness L1 may be about 2.8 μm.

In an embodiment, the thickness of the light blocking material layer BM may be less than the second thickness L2, which is the largest thickness. The thickness of the light blocking material layer BM may be greater than the third thickness L3, which is the smallest thickness. Accordingly, the second color filter CF2 may cover the inner surface of the second opening OP2 defined by the light blocking material layer BM, and the edge of the second color filter CF2 may cover a portion of the upper surface of the light blocking material layer BM connected to the inner surface of the second opening OP2. The third color filter CF3 may cover at least a portion of the inner surface of the third opening OP3 defined by the light blocking material layer BM. However, unlike the second color filter CF2, the third color filter CF3 may not cover the upper surface of the light blocking material layer BM.

As described above, as the difference between the thickness of the light blocking material layer BM and the thickness of the color filters is small, diffraction patterns generated by the step between the light blocking material layer BM and the color filters may be minimized. In order to minimize the difference between the thickness of the light blocking material layer BM and the thickness of the color filters, the thickness of the light blocking material layer BM may be smaller than the second thickness L2, which is the largest thickness, and the thickness of the light blocking material layer BM may be larger than the third thickness L3, which is the smallest thickness.

In an embodiment, the first color filter CF1 may vary depending on the thickness of the light blocking material layer BM. For example, when the thickness of the first color filter CF1 is larger than the thickness of the light blocking material layer BM, the first color filter CF1 may cover the inner surface of the first opening OP1 defined by the light blocking material layer BM, and the edge of the first color filter CF1 may cover a portion of the upper surface of the light blocking material layer BM connected to the inner surface of the first opening OP1. As another embodiment, when the thickness of the first color filter CF1 is smaller than the thickness of the light blocking material layer BM, the first color filter CF1 may cover the inner surface of the first opening OP1 defined by the light blocking material layer BM, and the edge of the first color filter CF1 may cover a portion of the upper surface of the light blocking material layer BM connected to the inner surface of the first opening OP1.

In an embodiment and as illustrated in FIG. 4, the first to third color filters CF1 to CF3, respectively, may not overlap each other. For example, the edge of the first color filter CF1 may not cover the second color filter CF2. The edge of the second color filter CF2 may not cover the first color filter CF1 and the third color filter CF3. The edge of the third color filter CF3 may not cover the second color filter CF2. As described below, in a plan view, the color filters CF1 to CF3 may not overlap each other and may each have an elliptical shape.

Because the color filter layer CF is arranged in the openings of the light blocking material layer BM and the color filters CF1 to CF3 do not overlap each other, a portion of the light blocking material layer BM between the color filters CF1 to CF3 may be exposed in an upward direction. For example, a portion of the light blocking material layer BM may be exposed in an upward direction between the color filters CF1 to CF3. A portion of the light blocking material layer BM exposed in an upward direction between the color filters CF1 to CF3 may be in direct contact with a lower surface of an overcoating layer OC disposed on the color filter layer CF and the light blocking material layer BM.

In an embodiment, the overcoating layer OC may be disposed on the color filter layer CF and the light blocking material layer BM. The overcoating layer OC may planarize the upper surfaces of the color filter layer CF and the light blocking material layer BM. In other embodiments, the overcoating layer OC may be omitted. The overcoating layer OC may cover the step formed between the color filter layer CF and the light blocking material layer BM. For example, the overcoating layer OC may include an organic material, such as resin, acrylic, BCB, or HMDSO. Moreover, in an embodiment, the overcoating layer OC may include a transparent material.

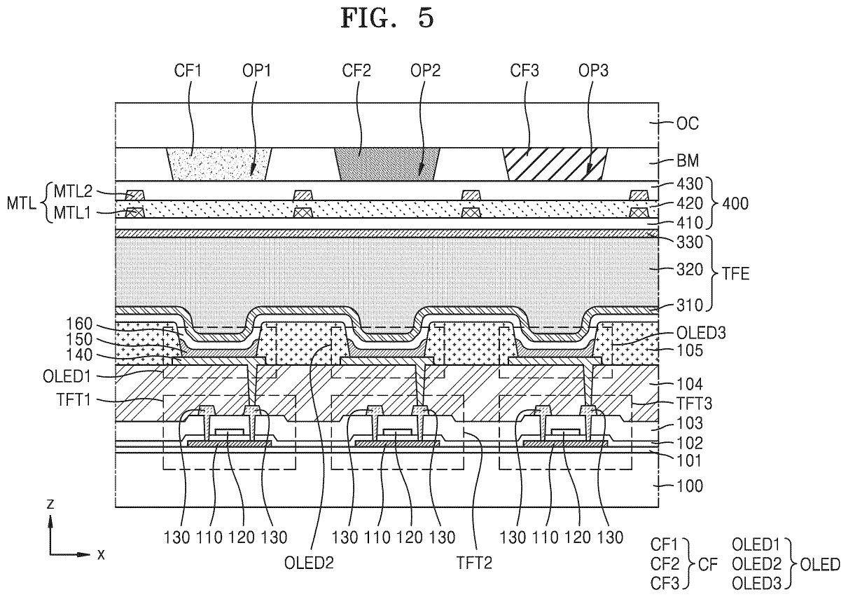

FIG. 5 is a cross-sectional view schematically illustrating an example of a portion of the display area of FIG. 1, according to an embodiment. In the following description of FIG. 5, the same or redundant description as provided above may be omitted.

In an embodiment and as illustrated in FIG. 5, an upper surface of a color filter layer CF and an upper surface of a light blocking material layer BM may be substantially flat and may form a continuous surface. An upper surface of each of color filters CF1 to CF3 may form a continuous surface with the upper surface of the light blocking material layer BM. The height of each of the color filters CF1 to CF3 may match the height of the light blocking material layer BM. These features may be similar to the features of the upper surface of the color filter layer CF and the upper surface of the light blocking material layer BM in FIG. 4. Specifically, the step between the upper surface of the color filter layer CF and the upper surface of the light blocking material layer BM in FIG. 4 represents the features of FIG. 5 in more detail and may be an exaggeration of the features of FIG. 5 for convenience of explanation.

In an embodiment and as illustrated in FIG. 5, the color filters CF1 to CF3 may not overlap each other. For example, the first color filter CF1 may not cover the second color filter CF2. The second color filter CF2 may not cover the first color filter CF1 and the third color filter CF3. The third color filter CF3 may not cover the second color filter CF2. In a plan view, the color filters CF1 to CF3 may not overlap each other and may each have an elliptical shape.

Because the color filter layer CF is arranged in the openings of the light blocking material layer BM and because the color filters CF1 to CF3 do not overlap each other, a portion of the light blocking material layer BM disposed between the color filters CF1 to CF3 may be exposed in an upward direction. For example, a portion of the light blocking material layer BM may be exposed in an upward direction between the color filters CF1 to CF3. A portion of the light blocking material layer BM exposed in an upward direction between the color filters CF1 to CF3 may be in direct contact with a lower surface of an overcoating layer OC which is disposed on the color filter layer CF and the light blocking material layer BM.

As described above, as the height difference between each of the color filters and the light blocking material layer BM decreases, diffraction patterns generated by the thickness difference between each of the color filters and the light blocking material layer BM may be reduced. By minimizing flatness distortion between the color filters and the light blocking material layer BM, diffraction patterns generated by the color filters may be significantly reduced. The thickness difference between the color filters and the light blocking material layer BM may be within about ±0.5 μm.

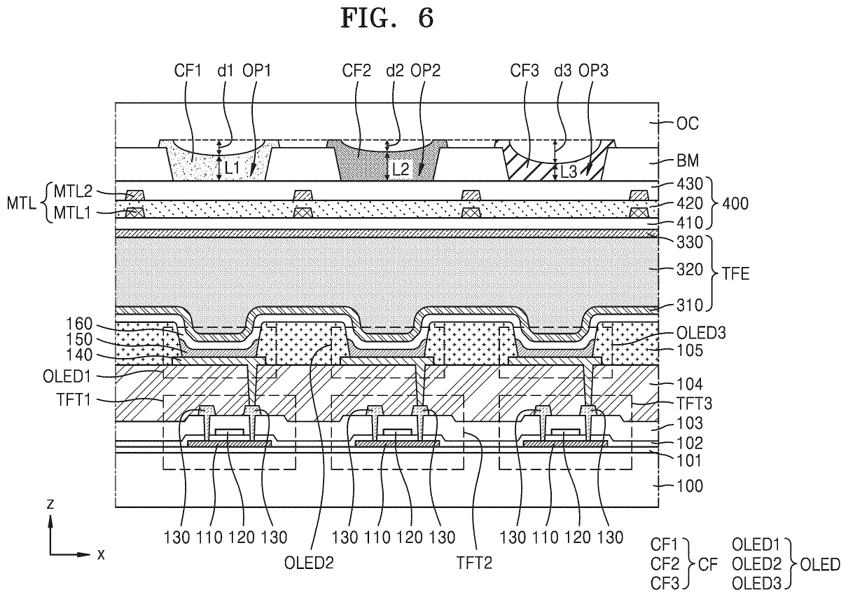

FIG. 6 is a cross-sectional view schematically illustrating an example of a portion of the display area of FIG. 1, according to an embodiment. In the following description of FIG. 6, the same or redundant description as provided above may be omitted.

In an embodiment and as illustrated in FIG. 6, the central portion of each of color filters CF1 to CF3 may have a concavely recessed shape (e.g., a recessed area). For example, the first color filter CF1 may have a first thickness L1, and the recessed depth of the first color filter CF1 may be a first depth d1. The second color filter CF2 may have a second thickness L2, and the recessed depth of the second color filter CF2 may be a second depth d2. The third color filter CF3 may have a third thickness L3, and the recessed depth of the third color filter CF3 may be a third depth d3.

In an embodiment, the first depth d1 may have the largest value among the depths between the upper surface of the recessed shape and the virtual upper surface when the first color filter CF1 is not recessed. The second depth d2 may have the largest value among the depths between the upper surface of the recessed shape and the virtual upper surface when the second color filter CF2 is not recessed. The third depth d3 may have the largest value among the depths between the upper surface of the recessed shape and the virtual upper surface when the third color filter CF3 is not recessed.

In an embodiment and as illustrated in FIG. 6, for example, the sum of the first thickness L1 and the first depth d1 may be substantially equal to the sum of the second thickness L2 and the second depth d2. The sum of the first thickness L1 and the first depth d1 may be substantially equal to the sum of the third thickness L3 and the third depth d3.

In an embodiment, considering the embodiments described with reference to FIGS. 4 and 6, the sum of the first thickness L1 and the first depth d1 may be less than the sum of the second thickness L2 and the second depth d2. The sum of the first thickness L1 and the first depth d1 may be larger than the sum of the third thickness L3 and the third depth d3. The sum of the second thickness L2 and the second depth d2 may be larger than the sum of the first thickness L1 and the first depth d1 and the sum of the third thickness L3 and the third depth d3. The sum of the third thickness L3 and the third depth d3 may be less than the sum of the first thickness L1 and the first depth d1 and the sum of the second thickness L2 and the second depth d2.

In an embodiment and referring to FIG. 6, the distance between the central area of the first color filter CF1 and the upper surface of the substrate 100 may be less than the distance between the upper surface of the light blocking material layer BM and the upper surface of the substrate 100. The distance between the central area of the second color filter CF2 and the upper surface of the substrate 100 may be less than the distance between the upper surface of the light blocking material layer BM and the upper surface of the substrate 100. The distance between the central area of the third color filter CF3 and the upper surface of the substrate 100 may be less than the distance between the upper surface of the light blocking material layer BM and the upper surface of the substrate 100.

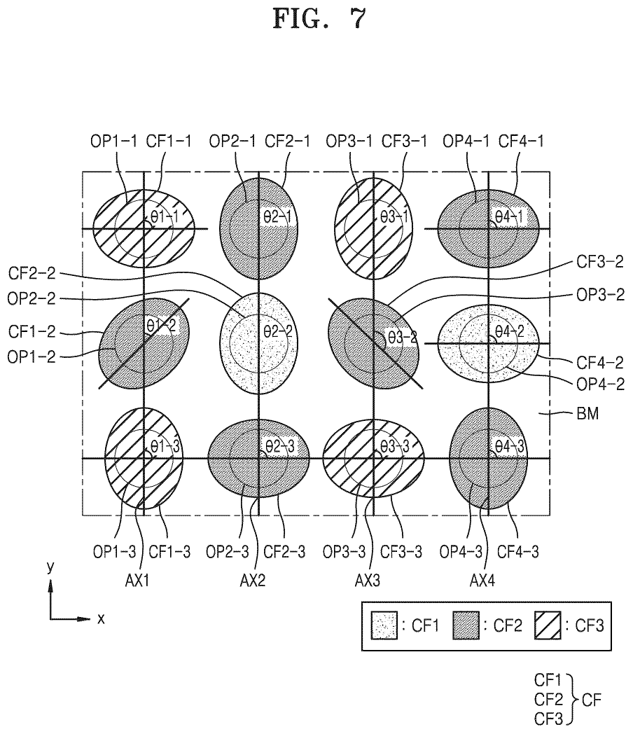

FIG. 7 is a plan view schematically illustrating an example of a color filter pattern arranged in an area A of FIG. 1, according to an embodiment. In the following description of FIG. 7, the same or redundant description as provided above may be omitted.

In an embodiment and as illustrated in FIG. 7, in a plan view, a pattern of a color filter layer CF may have an elliptical shape, where the elliptical shape may have a major axis and a minor axis and may have an eccentricity. In a plan view, a pattern of an opening formed in a light blocking material layer BM may have a circular shape. For convenience of explanation, terms such as a first-1 color filter CF1-1 or a first-1 opening OP1-1 are not associated with the first color filter and the first opening described above and may be terms used according to the order of arrangement in the drawings.

For example, in an embodiment, in a plan view, the color filter layer CF may include a first-1 color filter CF1-1, a first-2 color filter CF1-2, and a first-3 color filter CF1-3. In a plan view, the first-1 color filter CF1-1, the first-2 color filter CF1-2, and the first-3 color filter CF1-3 may have a midpoint disposed on a first virtual axis AX1 extending along the y-axis (e.g., the midpoint of the elliptical shape is the intersection of the major axis and the minor axis). In a plan view, the light blocking material layer BM may include a first-1 opening OP1-1, a first-2 opening OP1-2, and a first-3 opening OP1-3. In a plan view, the first-1 opening OP1-1, the first-2 opening OP1-2, and the first-3 opening OP1-3 may have a midpoint disposed on the first virtual axis AX1 extending along the y-axis.

A direction of the elliptical shape may be defined as a direction in which the major axis extends. A direction in which the first-1 color filter CF1-1 faces may have a first-1 angle θ1-1 with respect to the first virtual axis AX1. A direction in which the first-2 color filter CF1-2 faces may have a first-2 angle θ1-2 with respect to the first virtual axis AX1. A direction in which the first-3 color filter CF1-3 faces may have a first-3 angle θ1-3 with respect to the first virtual axis AX1. In addition, color filters disposed on the first virtual axis AX1 may have specific angles with respect to the first virtual axis AX1.

In an embodiment, the major axes of the first-1 color filter CF1-1, the first-2 color filter CF1-2, and the first-3 color filter CF1-3 may extend in a direction that is different from each other or may extend in a random direction.

For example, in an embodiment, the first-1 angle θ1-1, the first-2 angle θ1-2, and the first-3 angle θ1-3 may be one of about 0 degrees, about 45 degrees, about 90 degrees, and about 135 degrees. This may be an example of a case where there are four types of elliptical-shaped directions. In another embodiment, the first-1 angle θ1-1, the first-2 angle θ1-2, and the first-3 angle θ1-3 may be one of about 0 degrees, about 20 degrees, about 40 degrees, about 60 degrees, about 80 degrees, about 100 degrees, about 120 degrees, about 140 degrees, and about 160 degrees. This may be an example of a case where there are nine types of elliptical-shaped directions. The direction in which each elliptical shape arranged in a specific area faces may be randomly arranged, and the elliptical-shaped pattern may be repeated based on a specific area unit.

In an embodiment, in a plan view, the color filter layer CF may also, include a second-1 color filter CF2-1, a second-2 color filter CF2-2, and a second-3 color filter CF2-3. In a plan view, the second-1 color filter CF2-1, the second-2 color filter CF2-2, and the second-3 color filter CF2-3 may have a midpoint disposed on a second virtual axis AX2 extending along the y-axis (e.g., the midpoint of the elliptical shape is the intersection of the major axis and the minor axis). In a plan view, the light blocking material layer BM may include a second-1 opening OP2-1, a second-2 opening OP2-2, and a second-3 opening OP2-3. In a plan view, the second-1 opening OP2-1, the second-2 opening OP1-2, and the second-3 opening OP2-3 may have a midpoint disposed on the second virtual axis AX2 extending along the y-axis.

For example, the major axes of the second-1 color filter CF2-1, the second-2 color filter CF2-2, and the second-3 color filter CF2-3 may extend in a direction that is different from each other or may extend in a random direction.

A direction of the elliptical shape may be defined as a direction in which the major axis extends. A direction in which the second-1 color filter CF2-1 faces may have a second-1 angle θ2-1 with respect to the second virtual axis AX2. A direction in which the second-2 color filter CF2-2 faces may have a second-2 angle θ2-2 with respect to the second virtual axis AX2. A direction in which the second-3 color filter CF2-3 faces may have a second-3 angle θ2-3 with respect to the second virtual axis AX2. In addition, color filters disposed on the second virtual axis AX2 may have specific angles with respect to the second virtual axis AX2.

For example, in an embodiment, the second-1 angle θ2-1, the second-2 angle θ2-2, and the second-3 angle θ2-3 may be one of about 0 degrees, about 45 degrees, about 90 degrees, and about 135 degrees. This may be an example of a case where there are four types of elliptical-shaped directions. In another embodiment, the second-1 angle θ2-1, the second-2 angle θ2-2, and the second-3 angle θ2-3 may be one of about 0 degrees, about 20 degrees, about 40 degrees, about 60 degrees, about 80 degrees, about 100 degrees, about 120 degrees, about 140 degrees, and about 160 degrees. This may be an example of a case where there are nine types of elliptical-shaped directions. The direction in which each elliptical shape arranged in a specific area faces may be randomly arranged, and the elliptical-shaped pattern may be repeated based on a specific area unit.

In an embodiment, in a plan view, the color filter layer CF may include a third-1 color filter CF3-1, a third-2 color filter CF3-2, and a third-3 color filter CF3-3. In a plan view, the third-1 color filter CF3-1, the third-2 color filter CF3-2, and the third-3 color filter CF3-3 may have a midpoint disposed on a third virtual axis AX3 extending along the y-axis (e.g., the midpoint of the elliptical shape is the intersection of the major axis and the minor axis). In a plan view, the light blocking material layer BM may include a third-1 opening OP3-1, a third-2 opening OP3-2, and a third-3 opening OP3-3. In a plan view, the third-1 opening OP3-1, the third-2 opening OP3-2, and the third-3 opening OP3-3 may have a midpoint disposed on the third virtual axis AX3 extending along the y-axis.

For example, the major axes of the third-1 color filter CF3-1, the third-2 color filter CF2-2, and the third-3 color filter CF3-3 may extend in a direction that is different from each other or may extend in a random direction.

A direction of the elliptical shape may be defined as a direction in which the major axis extends. A direction in which the third-1 color filter CF3-1 faces may have a third-1 angle θ3-1 with respect to the third virtual axis AX3. A direction in which the third-2 color filter CF3-2 faces may have a third-2 angle θ3-2 with respect to the third virtual axis AX3. A direction in which the third-3 color filter CF3-3 faces may have a third-3 angle θ3-3 with respect to the third virtual axis AX3. In addition, color filters disposed on the third virtual axis AX3 may have specific angles with respect to the third virtual axis AX3.

For example, in an embodiment, the third-1 angle θ3-1, the third-2 angle θ3-2, and the third-3 angle θ3-3 may be one of about 0 degrees, about 45 degrees, about 90 degrees, and about 135 degrees. This may be an example of a case where there are four types of elliptical-shaped directions. In another embodiment, the third-1 angle θ3-1, the third-2 angle θ3-2, and the third-3 angle θ3-3 may be one of about 0 degrees, about 20 degrees, about 40 degrees, about 60 degrees, about 80 degrees, about 100 degrees, about 120 degrees, about 140 degrees, and about 160 degrees. This may be an example of a case where there are nine types of elliptical-shaped directions. The direction in which each elliptical shape arranged in a specific area faces may be randomly arranged, and the elliptical-shaped pattern may be repeated based on a specific area unit.

In an embodiment, in a plan view, the color filter layer CF may also include a fourth-1 color filter CF4-1, a fourth-2 color filter CF4-2, and a fourth-3 color filter CF4-3. In a plan view, the fourth-1 color filter CF4-1, the fourth-2 color filter CF4-2, and the fourth-3 color filter CF4-3 may have a midpoint disposed on a fourth virtual axis AX4 extending along the y-axis (e.g., the midpoint of the elliptical shape is the intersection of the major axis and the minor axis). In a plan view, the light blocking material layer BM may include a fourth-1 opening OP4-1, a fourth-2 opening OP4-2, and a fourth-3 opening OP4-3. In a plan view, the fourth-1 opening OP4-1, the fourth-2 opening OP4-2, and the fourth-3 opening OP4-3 may have a midpoint disposed on the fourth virtual axis AX4 extending along the y-axis.

For example, the major axes of the fourth-1 color filter CF4-1, the fourth-2 color filter CF4-2, and the fourth-3 color filter CF4-3 may extend in a direction that is different from each other or may extend in a random direction.

A direction of the elliptical shape may be defined as a direction in which the major axis extends. A direction in which the fourth-1 color filter CF4-1 faces may have a fourth-1 angle θ4-1 with respect to the fourth virtual axis AX4. A direction in which the fourth-2 color filter CF4-2 faces may have a fourth-2 angle θ4-2 with respect to the fourth virtual axis AX4. A direction in which the fourth-3 color filter CF4-3 faces may have a fourth-3 angle θ4-3 with respect to the fourth virtual axis AX4. In addition, color filters disposed on the fourth virtual axis AX4 may have specific angles with respect to the fourth virtual axis AX4.

For example, in an embodiment, the fourth-1 angle θ4-1, the fourth-2 angle θ4-2, and the fourth-3 angle θ4-3 may be one of about 0 degrees, about 45 degrees, about 90 degrees, and about 135 degrees. This may be an example of a case where there are four types of elliptical-shaped directions. In another embodiment, the fourth-1 angle θ4-1, the fourth-2 angle θ4-2, and the fourth-3 angle θ4-3 may be one of 0 about degrees, about 20 degrees, about 40 degrees, about 60 degrees, about 80 degrees, about 100 degrees, about 120 degrees, about 140 degrees, and about 160 degrees. This may be an example of a case where there are nine types of elliptical-shaped directions. The direction in which each elliptical shape arranged in a specific area faces may be randomly arranged, and the elliptical-shaped pattern may be repeated based on a specific area unit.

In addition, although not illustrated, in other embodiments, an n^{th} virtual axis extending along the y-axis and color filters and openings arranged along the n^{th} virtual axis may also have the above-described features.

As such, in a plan view, when the shape of the color filters is elliptical, the regularity of the pattern of the color filter layer CF may be reduced. As the regularity is reduced, diffraction patterns caused by the reflection and diffraction of external light may be reduced. As such, one of the features of the disclosure may be to reduce the regularity of the pattern shape of the color filter layer CF.

For example, in an embodiment, the first-1 color filter CF1-1, the first-3 color filter CF1-3, the third-1 color filter CF3-1, and the third-3 color filter CF3-3 may be color filters configured to transmit the same wavelength band (e.g., the third wavelength band). For example, the first-1 color filter CF1-1, the first-3 color filter CF1-3, the third-1 color filter CF3-1, and the third-3 color filter CF3-3 may be understood as the third color filter CF3 described above. This also applies to other drawings.

For another example, in an embodiment, the second-1 color filter CF2-1, the second-3 color filter CF2-3, the fourth-1 color filter CF4-1, and the fourth-3 color filter CF4-3 may be color filters configured to transmit the same wavelength band (e.g., the second wavelength band). For example, the second-1 color filter CF2-1, the second-3 color filter CF2-3, the fourth-1 color filter CF4-1, and the fourth-3 color filter CF4-3 may be understood as the third color filter CF3 described above. This also applies to other drawings.

Although only a portion is illustrated in the drawings, the first-2 color filter CF1-2, the first-4 color filter (not shown), the third-2 color filter CF3-2, and the third-4 color filter (not shown) may also be color filters configured to transmit the same wavelength band (e.g., the first wavelength band). For example, the first-2 color filter CF1-2, the first-4 color filter (not shown), the third-2 color filter CF3-2, and the third-4 color filter (not shown) may be understood as the first color filter CF1 described above. This also applies to other drawings.

For example, in an embodiment, the first-1 opening OP1-1, the first-3 opening OP1-3, the third-1 opening OP3-1, and the third-3 opening OP3-3 may be color filters configured to transmit the same wavelength band (e.g., the third wavelength band). For example, the first-1 opening OP1-1, the first-3 opening OP1-3, the third-1 opening OP3-1, and the third-3 opening OP3-3 may be understood as the third opening OP3 described above. This also applies to other drawings.

For another example, in an embodiment, the second-1 opening OP2-1, the second-3 opening OP2-3, the fourth-1 opening OP4-1, and the fourth-3 opening OP4-3 may be color filters configured to transmit the same wavelength band (e.g., the second wavelength band). For example, the second-1 opening OP2-1, the second-3 opening OP2-3, the fourth-1 opening OP4-1, and the fourth-3 opening OP4-3 may be understood as the third opening OP3 described above. This also applies to other drawings.

In an embodiment, although only a portion is illustrated in the drawings, the first-2 opening OP1-2, the first-4 opening (not shown), the third-2 opening OP3-2, and the third-4 opening (not shown) may also be color filters configured to transmit the same wavelength band (e.g., the first wavelength band). For example, the first-2 opening OP1-2, the first-4 opening (not shown), the third-2 opening OP3-2, and the third-4 opening not (not shown) may be understood as the first opening OP1 described above. This also applies to other drawings.

Accordingly, in an embodiment and referring to FIG. 7, the color filter layer CF may be disposed to be on the light-emitting elements and may be arranged to be on the same layer as the light blocking material layer BM. The color filter layer CF may include the color filters CF1 to CF3 described above. In a plan view, the color filters CF1 to CF3 may not overlap each other. In a plan view, each of the color filters CF1 to CF3 may have an elliptical shape.

In addition, in a plan view, it may be understood from the above description that the major axes of the color filters CF1 to CF3 may be different from each other so that the color filters CF1 to CF3 face different directions within a specific period.

For example, in an embodiment, in a plan view, the first color filter CF1 may have a first elliptical shape with a first major axis extending in a first direction. In a plan view, the second color filter CF2 may have a second elliptical shape with a second major axis extending in a second direction. In a plan view, the third color filter CF3 may have a third elliptical shape with a third major axis extending in a third direction. In a plan view, the first to third directions may be different from each other.

As described above, as the color filter layers CF configured to transmit the same wavelength band within a specific period are arranged differently or randomly, the regularity of the pattern of the color filter layer CF may be reduced. As the regularity is reduced, diffraction patterns caused by the reflection and diffraction of external light may be reduced.

In a plan view, each of the openings formed in the light blocking material layer BM may have a circular shape. However, this is only an example, and in other embodiments, the shapes of the openings in a plan view may be variously modified.

In a plan view, in an embodiment, the openings formed in the light blocking material layer BM may overlap the pattern shapes of the color filter layer CF. For example, in a plan view, the area of each of the pattern shape of the color filter layer CF may be larger than the area of each of the openings formed in the light blocking material layer BM. Accordingly, in a plan view, the openings formed in the light blocking material layer BM may be elements that are invisible due to the color filter layer CF.

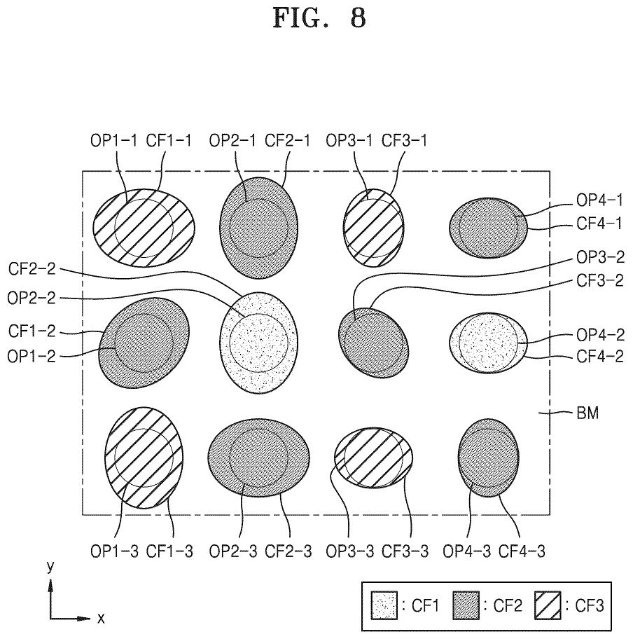

FIG. 8 is a plan view schematically illustrating an example of a color filter pattern arranged in the area A of FIG. 1, according to an embodiment. In the following description of FIG. 8, the same or redundant description as provided above may be omitted.

In an embodiment and as illustrated in FIG. 8, in a plan view, the pattern shapes of the color filter layer CF may have elliptical shapes, and the directions in which the elliptical shapes face may be different from each other. In addition, in a plan view, the areas of the elliptical shapes may be different from each other.

For example, in a plan view, the areas of the color filters CF1-1 to CF1-3 may be equal to each other. In a plan view, the areas of the color filters CF2-1 to CF2-3 may be equal to each other.

Additionally, in a plan view, the areas of the color filters CF3-1 to CF3-3 may be equal to each other. However, the area of each of the color filters CF3-1 to CF3-3 may be different from the area of each of the color filters CF1-1 to CF1-3. The area of each of the color filters CF3-1 to CF3-3 may be different from the area of each of the color filters CF2-1 to CF2-3.

For example, in an embodiment, in a plan view, the areas of the color filters arranged in a specific region of the area A may be equal to each other and the areas of the color filters arranged in regions other than the specific region of the area A may be equal to each other. However, in a plan view, the area of each of the color filter arranged in a specific region may be different from the area of each of the color filters arranged in the remaining regions.

In a plan view, in an embodiment, the first color filter CF1 may have a first elliptical shape with a first major axis extending in the first direction. In a plan view, the second color filter CF2 may have a second elliptical shape with a second major axis extending in the second direction. In a plan view, the third color filter CF3 may have a third elliptical shape with a third major axis extending in the third direction.

Also, in a plan view, the eccentricities of the first to third elliptical shapes may be different from each other. The eccentricity of each of the first to third elliptical shapes may be between about 0.5 and about 0.8. Specifically, when the eccentricity of the elliptical shape is less than about 0.5, the elliptical shape may have an excessively elongated shape in a plan view, making it difficult to form the elliptical shape through an etching process. In addition, when the eccentricity of the elliptical shape is greater than about 0.8, the elliptical shape is observed to be almost circular, and thus, the amount of decrease in diffraction patterns may be reduced to an extent that is visually confirmed.

In another embodiment, the area of each of the color filters arranged in the area A may have a random size.

As described above, in a plan view, as the regularity of the area of each of the color filter layers CF is reduced, diffraction patterns caused by the reflection and diffraction of external light may be reduced. As such, one of the features of the invention may be to reduce the regularity of the pattern shape of the color filter layer CF.

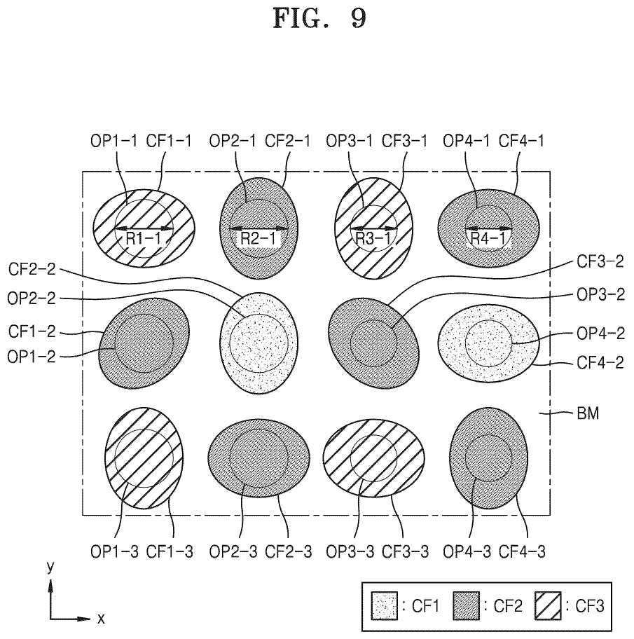

FIG. 9 is a plan view schematically illustrating an example of a color filter pattern arranged in the area A of FIG. 1, according to an embodiment. In the following description of FIG. 9, the same or redundant description as provided above may be omitted.

As illustrated in FIG. 9, in a plan view, the diameters of the openings may be different from each other. For example, openings formed in a light blocking material layer BM may include at least first-1 to first-3 openings OP1-1 to OP1-3, respectively, second-1 to second-3 openings OP2-1 to OP2-3, respectively, third-1 to third-3 openings OP3-1 to OP3-3, respectively, and fourth-1 to fourth-3 openings OP4-1 to OP4-3, respectively.

The diameters of the openings arranged in a row along the y-axis, such as the first-1 to first-3 openings OP1-1 to OP1-3, respectively, may be equal to each other. The diameters of the openings arranged in a row along the y-axis, such as the second-1 to second-3 openings OP2-1 to OP2-3, respectively, may be equal to each other. The diameters of the openings arranged in a row along the y-axis, such as the third-1 to third-3 openings OP3-1 to OP3-3, respectively, may be equal to each other. In this embodiment, a first-1 diameter R1-1 of the first-1 opening OP1-1 may be greater than a third-1 diameter R3-1 of the third-1 opening OP3-1 or a fourth-1 diameter R4-1 of the fourth-1 opening OP4-1. Also, a second-1 diameter R2-1 of the second-1 opening OP2-1 may be greater than the third-1 diameter R3-1 of the third-1 opening OP3-1 or the fourth-1 diameter R4-1 of the fourth-1 opening OP4-1.

Thus, by varying the diameters of the openings as described above, the regularity of the pattern of the color filter layer CF arranged in the openings may be reduced. For example, the color filter layer CF may fill the opening, and the regularity of the pattern of the color filter layer CF filling the opening may be reduced. As described above, as the regularity of the pattern of the color filter layer CF is reduced, diffraction patterns caused by the reflection and diffraction of external light may be reduced. As such, one of the features of the invention may be to reduce the regularity of the pattern shape of the color filter layer CF.

Although FIG. 9 illustrates that the first-1 diameter R1-1 and the second-1 diameter R2-1 are equal to or similar to each other, this is only an example and the scope of the invention is not limited thereto.

In an embodiment and referring to FIG. 9, in a plan view, the areas of the openings OP1 to OP3 may be different from each other. In an embodiment, in a plan view, the areas of the first-1 opening OP1-1, the second-1 opening OP2-1, the third-1 opening OP3-1, and the fourth-1 opening OP4-1 may be different from each other. In other embodiments, the areas of some of the first-1 opening OP1-1, the second-1 opening OP2-1, the third-1 opening OP3-1, and the fourth-1 opening OP4-1 may be different from each other.

In an embodiment and referring to FIG. 9, in a plan view, the area of the opening may be understood as being replaced by the diameter of the opening. Accordingly, in a plan view, the diameters of the openings OP1 to OP3 may be different from each other. In some embodiments, in a plan view, the diameters of some of the openings OP1 to OP3 may be different from each other. In other embodiments, in a plan view, the diameters of the first-1 opening OP1-1, the second-1 opening OP2-1, the third-1 opening OP3-1, and the fourth-1 opening OP4-1 may be different from each other and in still other embodiments the diameters of some of the first-1 opening OP1-1, the second-1 opening OP2-1, the third-1 opening OP3-1, and the fourth-1 opening OP4-1 may be different from each other.

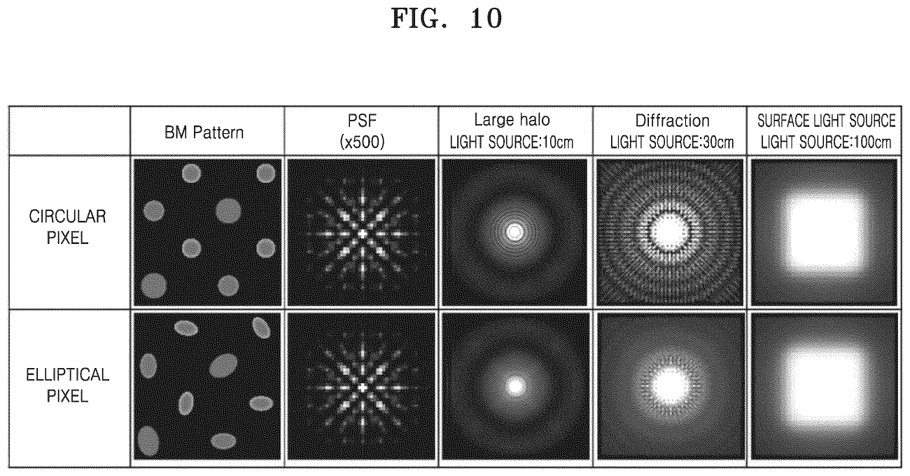

FIG. 10 is a table comparing the effects of examples of color filter patterns, according to an embodiment.

In the following description of FIG. 10, the same or redundant description as provided above may be omitted.

As illustrated in FIG. 10, it is shown that a circular pixel with a circular pattern has a larger halo than an elliptical pixel with an elliptical pattern. In addition, when comparing the diffraction degrees of the circular pixel and the elliptical pixel with respect to a light source with a diameter of about 30 cm, it is shown that the diffraction degree of the circular pixel is greater than the diffraction degree of the elliptical pixel. However, according to FIG. 10, in the case of a surface light source with a width of about 100 cm, it can be seen that there is no significant difference in the diffraction degree between the circular pixel and the elliptical pixel.

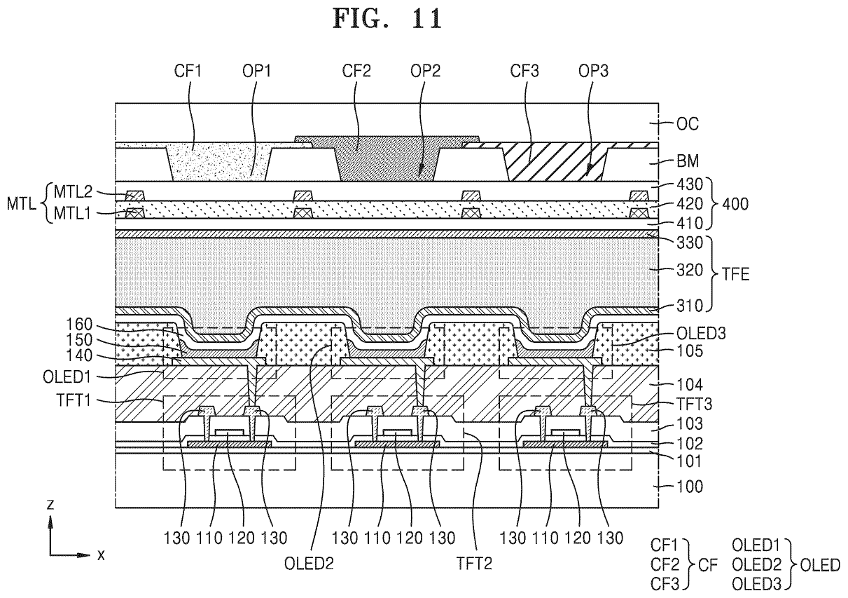

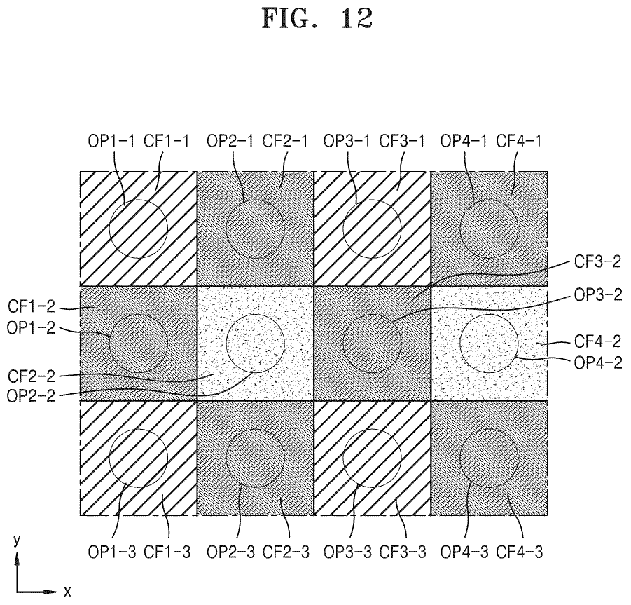

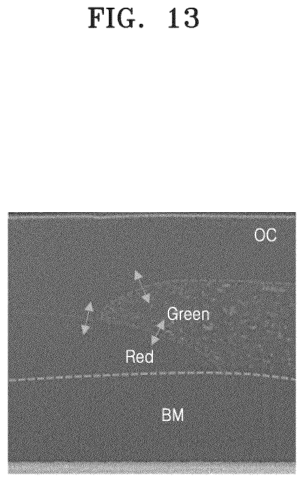

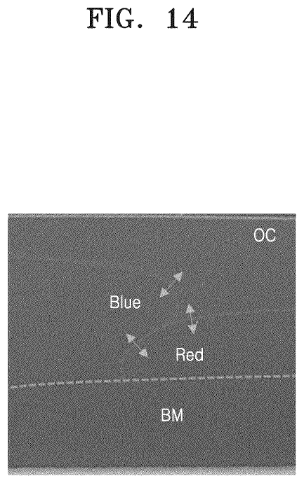

FIG. 11 is a cross-sectional view schematically illustrating a portion of a display area of a display apparatus, according to a comparative example, FIG. 12 is a plan view schematically illustrating an example of a color filter pattern in a display area of a display apparatus, according to a comparative example, and FIGS. 13 and 14 are cross-sectional views schematically illustrating the overlapping shapes of edges of color filters in a display apparatus, according to a comparative example.

In the following description of FIGS. 11 to 14, the same or redundant description as provided above may be omitted.

As illustrated in FIGS. 11 to 14, a light blocking material layer BM may include a first opening OP1 and a second opening OP2. A first color filter CF1 may be arranged in the first opening OP1, and a second color filter CF2 may be arranged in the second opening OP2. The edge of the first color filter CF1 may cover the upper surface of the light blocking material layer BM that defines the first opening OP1, and the edge of the second color filter CF2 may cover the upper surface of the light blocking material layer BM that defines the second opening OP2.

The edge of the second color filter CF2 disposed around the first color filter CF1 may cover both the upper surface of the light blocking material layer BM and the edge of the adjacent first color filter CF1. As a result, the edge of the first color filter CF1 and the edge of the second color filter CF2 may be disposed to overlap each other on the light blocking material layer BM.

The light blocking material layer BM may further include a third opening OP3. A third color filter CF3 may be arranged in the third opening OP3, and the edge of the third color filter CF3 may cover the upper surface of the light blocking material layer BM that defines the third opening OP3.

The edge of the second color filter CF2 disposed around the third color filter CF3 may cover both the upper surface of the light blocking material layer BM and the edge of the adjacent third color filter CF3. As a result, the edge of the third color filter CF3 and the edge of the second color filter CF2 may be disposed to overlap each other on the light blocking material layer BM.

As such, when a region where the color filters overlap each other is formed, a diffraction phenomenon which occurs due to the color filter layer CF may be further strengthened due to the difference in the refractive index of each color filter and the flatness distortion that occurs in the color filter. Due to this, a user is able to observe diffraction patterns, and thus, the image quality of the display apparatus is reduced.

In the display apparatus according to the comparative example, the light blocking material layer BM may be covered with the color filter layer CF in a plan view. As a result, because the light blocking material layer BM is covered with the color filter layer CF, the light blocking material layer BM may not be exposed in an upward direction.

Therefore, a height difference in the color filter layer CF may occur and may be as much as the height of the light blocking material layer BM, and this height difference may generate a large halo and a larger diffraction pattern.

FIG. 13 is a cross-sectional view illustrating a region where color filters for different colors overlap each other, according to a comparative example. In this case, the diffraction pattern mentioned in the disclosure may be generated by the curved shape of the region where color filters for different colors overlap each other.

In addition, FIG. 14 is a cross-sectional view illustrating a region where the color filter layers CF with different refractive indices overlap each other, according to a comparative example. In this case, the diffraction pattern mentioned in the disclosure may be generated due to the difference in refractive index of color filters in the region where the color filters with different refractive indices overlap each other.

As such, the diffraction pattern may be generated by external light reflected from the color filter layer CF due to two factors shown in FIGS. 13 and 14.

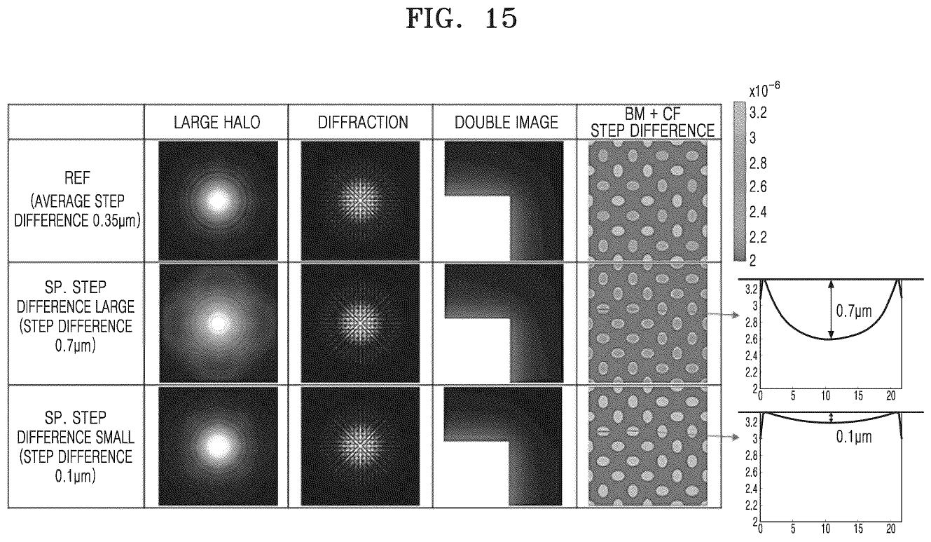

FIG. 15 is a table showing result data obtained from a comparative experiment on the degree of diffraction according to a step between a color filter layer CF and a light blocking material layer BM.

For a reference sample, an average step difference between the color filter layer CF and the light blocking material layer BM is about 0.35 μm. For a sample with a large step difference, an average step difference between the color filter layer CF and the light blocking material layer BM is about 0.7 μm. For a sample with a small step difference, an average step difference between the color filter layer CF and the light blocking material layer BM is about 0.1 μm. Referring to FIG. 15, it is shown that the degree of diffraction is reduced as the step difference between the color filter layer CF and the light blocking material layer BM is reduced.

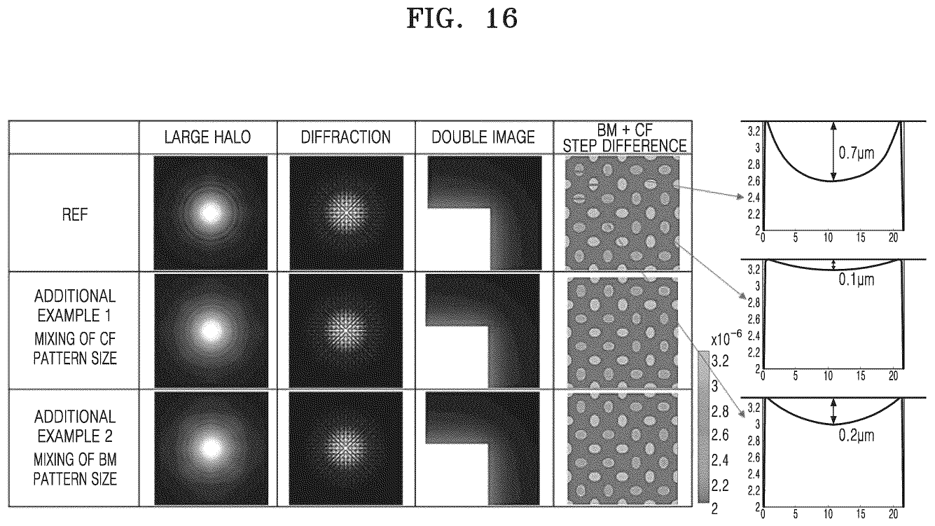

FIG. 16 is a table showing result data obtained from a comparative experiment on the degree of diffraction according to the sizes of the color filter layer CF and the light blocking material layer BM.

For a reference sample, in a plan view, the pattern of the color filter and the pattern of the light blocking material layer BM have the same size. Additional Example 1 is a sample in which the size of the pattern of the color filter was varied, and Additional Example 2 is a sample in which the size of the pattern of the light blocking material layer BM was varied. Referring to FIG. 16, it is shown that the degree of diffraction when the size of the pattern of the color filter or the pattern of the light blocking material layer BM in a plan view is varied is reduced more than the degree of diffraction in the case of the reference sample in which the degree of diffraction is not varied.

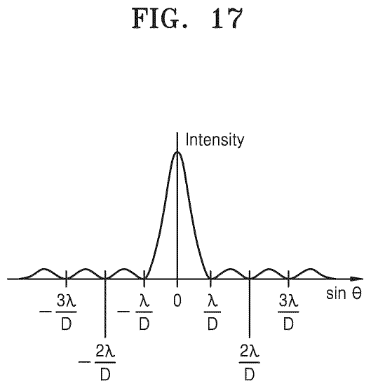

FIG. 17 is a graph schematically showing a position at which a diffraction pattern appears, according to an embodiment.

Referring to FIG. 17, the diffraction pattern may be a pattern in which peak/valley positions are repeated in inverse proportion to a slit width (a pattern size). For example, the y-axis of FIG. 17 may be the intensity of light measured outside of the display apparatus due to the reflection of light generated from an external light source as a result of constructive or destructive interference. In this case, A may be a wavelength (nm) of light generated from the external light source, and D may be a diameter (nm) of the opening formed in the light blocking material layer BM in a plan view. The units of A and D may be changed, but the same units are used. It is necessary to induce the pieces of reflected light to cause destructive interference.

From the viewpoint of causing destructive interference, a ratio of the areas of the color filters measured in a plan view may be adjusted. For example, when color filters having different areas are included as illustrated in FIG. 8, an area ratio of the area of one color filter in a plan view to the area of another color filter in a plan view may be about 2:3. As such, when the area ratio is about 2:3, the diffraction pattern formed by the reflection of external light may be minimized. In addition, various other area ratios may make it possible for destructive interference to occur, but the area ratio of about 2:3 is desirable.

From the viewpoint of causing destructive interference, an area ratio of the areas of the openings of the light blocking material layer BM, which are measured in a plan view, may be adjusted. For example, when the light-shielding filter layer includes openings having different areas as illustrated in FIG. 9, the area ratio of the area of one opening to the area of another opening in a plan view may be about 2:3. As such, when the area ratio is about 2:3, the diffraction pattern formed by the reflection of external light may be minimized. In addition, various other area ratios may make it possible for destructive interference to occur, but the area ratio of about 2:3 is desirable.

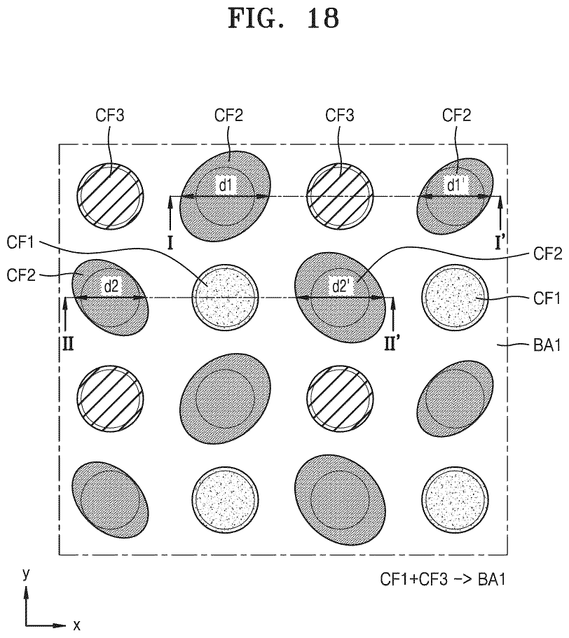

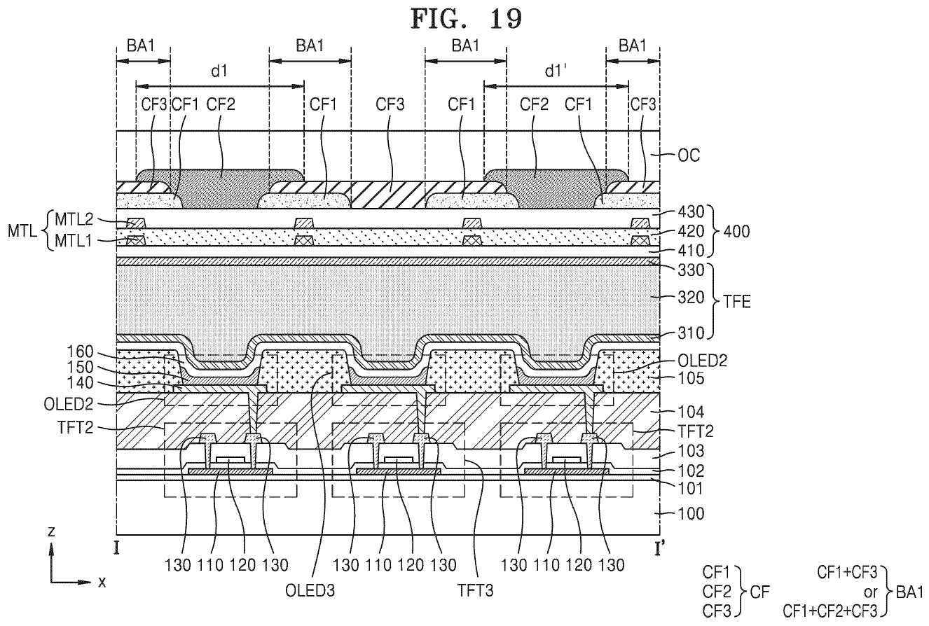

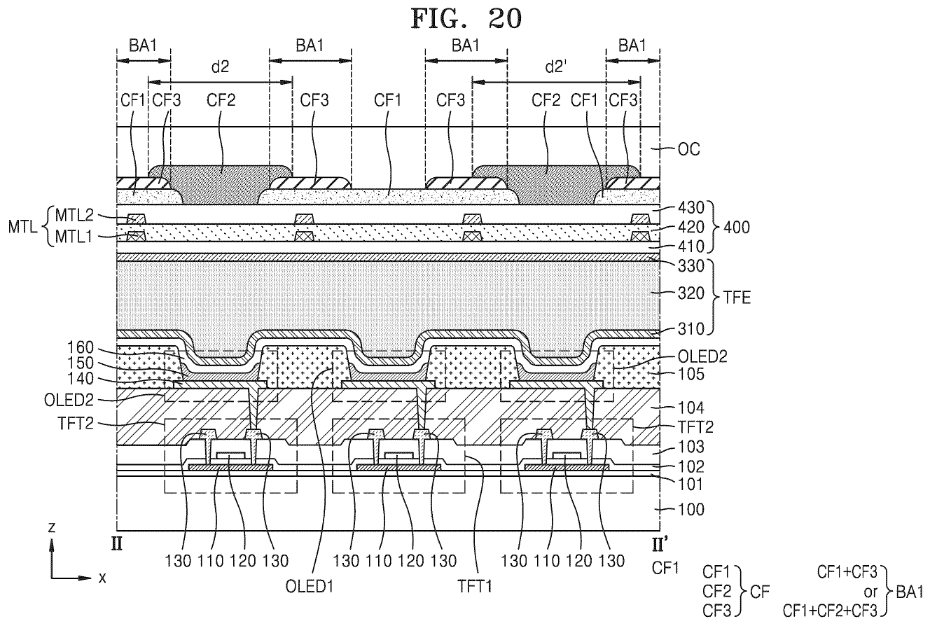

FIG. 18 is a plan view illustrating a portion of a display apparatus, focusing on a color filter layer CF and a light blocking material layer BM, according to another embodiment, FIG. 19 is a cross-sectional view of the display apparatus of FIG. 18 taken along line I-I′ of FIG. 18, and FIG. 20 is a cross-sectional view of the display apparatus of FIG. 18 taken along line II-II′ of FIG. 18.

In the following description of FIGS. 18 to 20, the same or redundant description as provided above may be omitted.

As illustrated in FIGS. 18 to 20, the display apparatus, according to another embodiment, may replace the light blocking material layer BM with the color filter layer CF. Thus, instead of forming a separate light blocking material layer BM, the color filters included in the color filter layer CF may be overlapped to act as the light blocking material layer BM.

When the light blocking material layer BM is replaced due to the overlapping of the color filters, the function of blocking internal light and/or external light may be mainly performed by a first color filter CF1 and a third color filter CF3. Therefore, changing the design of the color filter pattern may be mainly accomplished by changing the size of a second color filter CF2.

For example, as illustrated in FIGS. 18 to 20, an area where the existing light blocking material layer BM is present may be referred to as a first replacement area BA1. As illustrated in FIGS. 19 and 20, the first replacement area BA1 may be formed by the overlapping of the first color filter CF1 (e.g., a color filter configured to transmit a blue wavelength band) and the third color filter CF3 (e.g., a color filter configured to transmit a red wavelength band). In another embodiment, a portion of the first replacement area BA1 may be formed by overlapping the first color filter CF1, the second color filter CF2, and the third color filter CF3.

As illustrated in FIG. 18, in a plan view, the areas of the second color filters CF2 may have various sizes, and in a plan view, the shapes of the second color filters CF2 may be elliptical shapes with different sizes. In a plan view, each of the first color filter CF1 and the third color filter CF3 may have a circular shape.

Additionally, as illustrated in FIG. 19, the second color filter CF2 may be disposed on a second light-emitting element OLED2 which is configured to generate light in the second wavelength band, and the edges of the first color filter CF1 and the third color filter CF3 disposed on the first color filter CF1 may be used to define the pattern of the second color filter CF2. Similarly, the third color filter CF3 may be disposed on a third light-emitting element OLED3 which is configured to generate light in the third wavelength band.

Moreover, as illustrated in FIG. 19, the first color filter CF1 may be disposed on a first touch conductive layer MTL1 and a second touch conductive layer MTL2. The edge of the third color filter CF3 may cover the upper surface of the first color filter CF1. As a result, the first touch conductive layer MTL1 and the second touch conductive layer MTL2 may be covered with the first color filter CF1 and the third color filter CF3 and at least a portion of external light or internal light may be blocked by the first color filter CF1 and the third color filter CF3.

Also, as illustrated in FIGS. 18 and 19, because the size of the second color filter CF2 may be variously formed, widths d1 and d1′ of the second color filter CF2 which are measured along the cutting line I-I′ in a plan view may vary depending on a position at which the second color filter CF2 is located. As a result, diffraction patterns formed by reflection of external light due to the various widths of the second color filters CF2 may be minimized.

As illustrated in FIG. 20, the first color filter CF1 may be disposed on the first light-emitting element OLED1 which is configured to generate light in the first wavelength band. In a plan view, the first color filter CF1 may cover the first touch conductive layer MTL1 and the second touch conductive layer MTL2 and may also cover the first light-emitting element OLED1. For example, the edge of the first color filter CF1 may be disposed on the first touch conductive layer MTL1 and the second touch conductive layer MTL2, and the central area of the first color filter CF1 may be disposed on the first light-emitting element OLED1. Additionally, the third color filter CF3 may be disposed on the edge of the first color filter CF1, and the third color filter CF3 may also be disposed on the first touch conductive layer MTL1 and the second touch conductive layer MTL2.

Also as illustrated in FIG. 20, the second color filter CF2 may be disposed on the second light-emitting element OLED2 which is configured to generate light in the second wavelength band. For example, the edge of the second color filter CF2 may be disposed on the edge of the first color filter CF1, and the central area of the second color filter CF2 may be disposed on the second light-emitting element OLED2. Because changing the design of the color filter pattern is mainly accomplished by changing the size of the second color filter CF2, the size of the second color filter CF2 may be changed according to the ratio at which the edge of the second color filter CF2 covers the third color filter CF3 which is disposed on the edge of the first color filter CF1.

As illustrated in FIGS. 18 and 20, because the size of the second color filter CF2 may be variously formed, widths d2 and d2′ of the second color filter CF2 which are measured along the cutting line II-II′ in a plan view may vary depending on a position at which the second color filter CF2 is located. As a result, diffraction patterns formed by reflection of external light due to the various widths of the second color filters CF2 may be minimized.

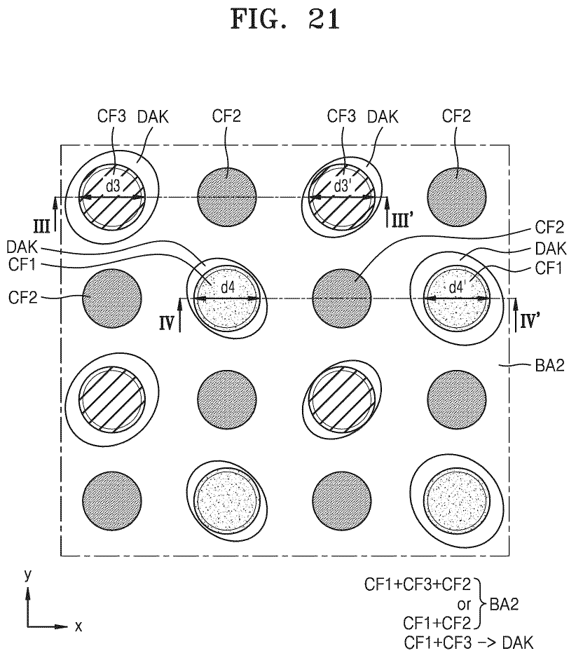

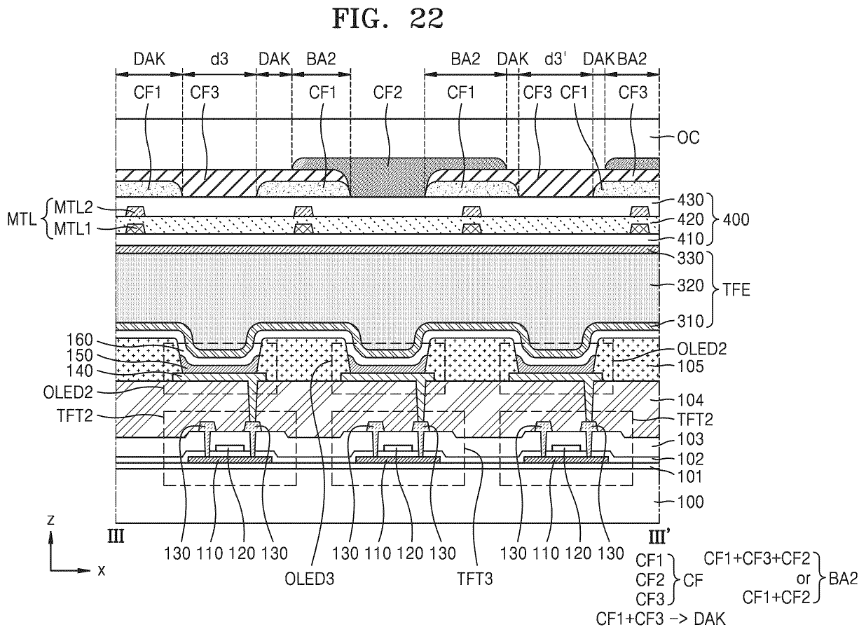

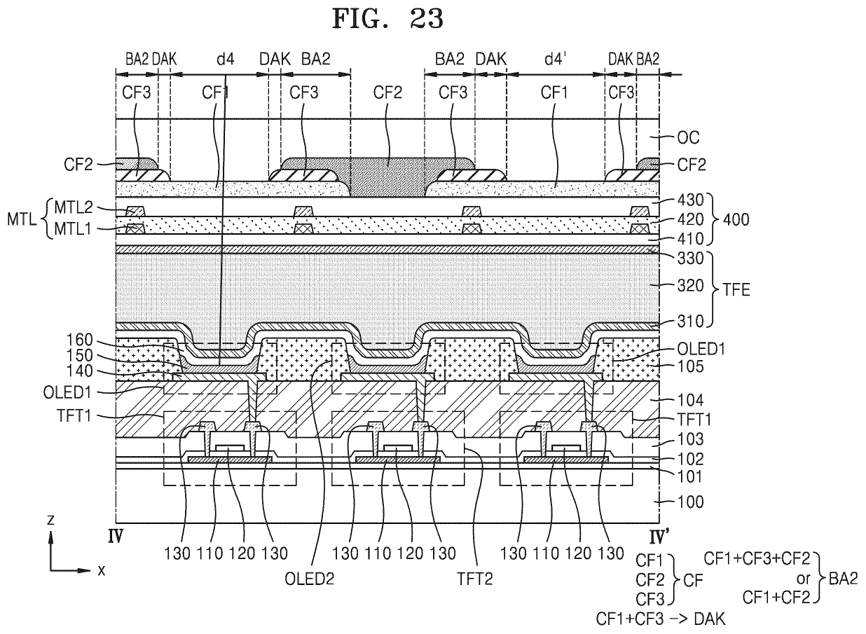

FIG. 21 is a plan view illustrating a portion of a display apparatus, focusing on a color filter layer CF and a light blocking material layer BM, according to another embodiment, FIG. 22 is a cross-sectional view of the display apparatus of FIG. 21 taken along line III-III′ of FIG. 21, and FIG. 23 is a cross-sectional view of the display apparatus of FIG. 21 taken along line IV-IV′ of FIG. 21.

In the following description of FIGS. 21 to 23, the same or redundant description as provided above may be omitted.

As illustrated in FIGS. 21 to 23, a display apparatus, according to another embodiment, may replace the light blocking material layer BM with the color filter layer CF. As described above, the function of blocking internal light and/or external light may be mainly performed by a first color filter CF1 and a third color filter CF3. Therefore, changing the design of the color filter pattern may be mainly accomplished by changing the size of a second color filter CF2.

For example, as illustrated in FIGS. 21 to 23, an area where the existing light blocking material layer BM is present may be referred to as a second replacement area BA2. As illustrated in FIGS. 22 and 23, the second replacement area BA2 may be formed by the overlapping of a first color filter CF1 (e.g., a color filter configured to transmit a blue wavelength band), a third color filter CF3 disposed on the first color filter CF1 (e.g., a color filter configured to transmit a red wavelength band), and a second color filter CF2 disposed on the third color filter CF3 (e.g., a color filter configured to transmit a green wavelength band). In another embodiment, the second replacement area BA2 may be formed by the overlapping of the first color filter CF1 and the second color filter CF2.

Additionally, as illustrated in FIGS. 21 to 23, an area that overlaps the first color filter CF1 in a plan view among areas where the second color filter CF2 is removed may be an erase area DAK, where the erase area DAK may be formed by the overlapping of the first color filter CF1 and the third color filter CF3.

Also, as illustrated in FIG. 22, the second color filter CF2 may be disposed on a second light-emitting element OLED2 which is configured to generate light in the second wavelength band, and the edges of the first color filter CF1 and the third color filter CF3 disposed on the first color filter CF1 may be used to define the pattern of the second color filter CF2. Similarly, the third color filter CF3 may be disposed on a third light-emitting element OLED3 which is configured to generate light in the third wavelength band.

As illustrated in FIG. 22, the first color filter CF1 may be disposed on a first touch conductive layer MTL1 and a second touch conductive layer MTL2. The edge of the third color filter CF3 may cover the upper surface of the first color filter CF1. As a result, the first touch conductive layer MTL1 and the second touch conductive layer MTL2 may be covered with the first color filter CF1 and the third color filter CF3 and at least a portion of external light or internal light may be blocked by the first color filter CF1 and the third color filter CF3.

As illustrated in FIG. 23, the first color filter CF1 may be disposed on the first light-emitting element OLED1 which is configured to generate light in the first wavelength band. Additionally, in a plan view, the first color filter CF1 may cover the first touch conductive layer MTL1 and the second touch conductive layer MTL2 and may also cover the first light-emitting element OLED1. For example, the edge of the first color filter CF1 may be disposed on the first touch conductive layer MTL1 and the second touch conductive layer MTL2, and the central area of the first color filter CF1 may be disposed on the first light-emitting element OLED1. Moreover, the third color filter CF3 may be disposed on the edge of the first color filter CF1, and the third color filter CF3 may be disposed on the first touch conductive layer MTL1 and the second touch conductive layer MTL2.

Furthermore, as illustrated in FIG. 23, the second color filter CF2 may be disposed on the second light-emitting element OLED2 which is configured to generate light in the second wavelength band. For example, the edge of the second color filter CF2 may be disposed on the edge of the first color filter CF1, and the central area of the second color filter CF2 may be disposed on the second light-emitting element OLED2.

As illustrated in FIGS. 21 to 23, the distance between the second color filters CF2 may be variously formed. In a plan view, diameters d3 and d3′ of openings included in the first color filter CF1, which are measured along the cutting line III-III′, may be equal to each other. Additionally, in a plan view, diameters d4 and d4′ of openings included in the third color filter CF3, which are measured along the cutting line IV-IV′, may be equal to each other. In summary, the diameters d3 and d3′ of the openings included in the first color filter CF1 may be different from the diameters d4 and d4′ of the openings included in the third color filter CF3. As a result, diffraction patterns formed when external light is reflected by various diameters of the openings included in the first color filter CF1 may be minimized.

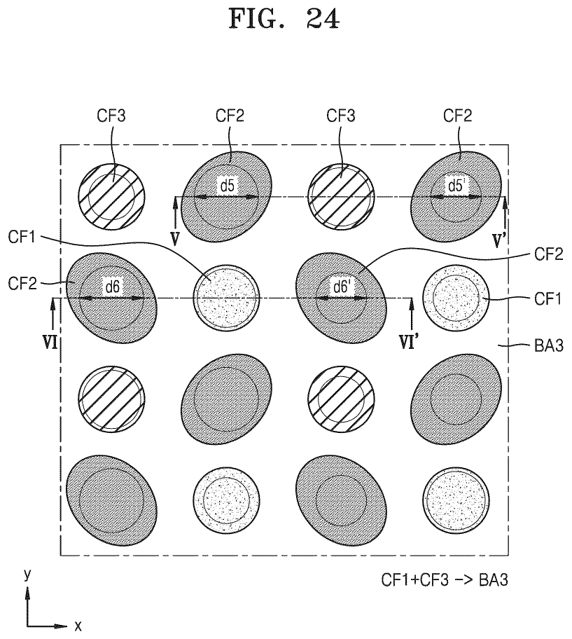

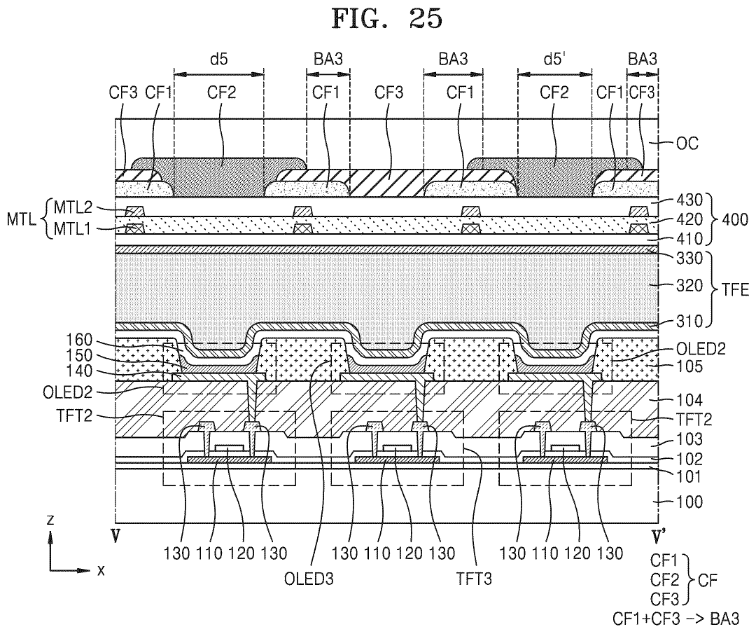

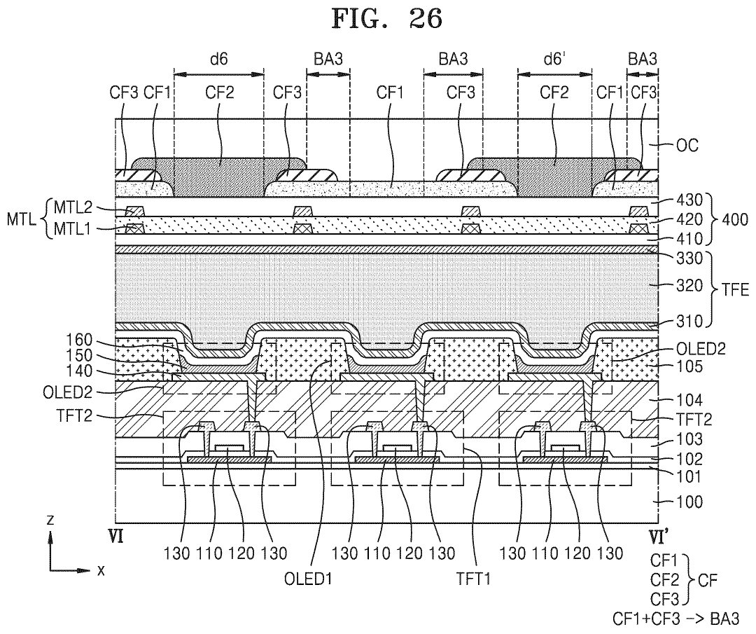

FIG. 24 is a plan view illustrating a portion of a display apparatus, focusing on a color filter layer CF and a light blocking material layer BM, according to another embodiment, FIG. 25 is a cross-sectional view of the display apparatus of FIG. 24 taken along line V-V′ of FIG. 24, and FIG. 26 is a cross-sectional view of the display apparatus of FIG. 24 taken along line VI-VI′ of FIG. 24.

In the following description of FIGS. 24 to 26, the same or redundant description as provided above may be omitted.

As illustrated in FIGS. 24 to 26, the display apparatus, according to another embodiment, may replace the light blocking material layer BM with the color filter layer CF. As described above, the function of blocking internal light and/or external light may be mainly performed by a first color filter CF1 and a third color filter CF3. Therefore, changing the design of the color filter pattern may be mainly accomplished by changing the size of a second color filter CF2.

As illustrated in FIG. 24, an area where the existing light blocking material layer BM is present may be referred to as a third replacement area BA3. As illustrated in FIGS. 25 and 26, the third replacement area BA3 may be formed by the overlapping of the first color filter CF1 (e.g., a color filter configured to transmit a blue wavelength band) and the third color filter CF3 (e.g., a color filter configured to transmit a red wavelength band).

As illustrated in FIG. 25, the second color filter CF2 may be disposed on a second light-emitting element OLED2 which is configured to generate light in the second wavelength band, and the edges of the first color filter CF1 and the third color filter CF3 disposed on the first color filter CF1 may be used to define the pattern of the second color filter CF2. Similarly, the third color filter CF3 may be disposed on a third light-emitting element OLED3 which is configured to generate light in the third wavelength band.

For example, as illustrated in FIG. 25, the first color filter CF1 may be disposed on a first touch conductive layer MTL1 and a second touch conductive layer MTL2. The edge of the third color filter CF3 may cover the upper surface of the first color filter CF1. As a result, in a plan view, the first touch conductive layer MTL1 and the second touch conductive layer MTL2 may be covered with the first color filter CF1 and the third color filter CF3. At least a portion of external light or internal light may be blocked by the first color filter CF1 and the third color filter CF3.

As illustrated in FIGS. 24 and 25, distances d5 and d5′ between the first color filters CF1 replacing the light blocking material layer BM may be variously formed. The distance d5 and d5′ between the first color filters CF1 measured along the cutting line V-V′ in a plan view may vary depending on a position at which the first color filter CF1 is located. For example, the distances d5 and d5′ between the first color filters CF1 may be the diameters of the openings defined by the first color filter CF1 in a plan view. As a result, the diffraction patterns formed when external light is reflected by various diameters of the openings defined by the first color filter CF1 may be minimized.

Additionally, as illustrated in FIG. 26, the first color filter CF1 may be disposed on the first light-emitting element OLED1 which is configured to generate light in the first wavelength band. The first color filter CF1 may cover the first touch conductive layer MTL1 and the second touch conductive layer MTL2 in a plan view and may also cover the first light-emitting element OLED1. Also, the edge of the first color filter CF1 may be disposed on the first touch conductive layer MTL1 and the second touch conductive layer MTL2, and the central area of the first color filter CF1 may be disposed on the first light-emitting element OLED1. The third color filter CF3 may be disposed on the edge of the first color filter CF1, and the third color filter CF3 may be disposed on the first touch conductive layer MTL1 and the second touch conductive layer MTL2.

For example, as illustrated in FIG. 26, the second color filter CF2 may be disposed on the second light-emitting element OLED2 which is configured to generate light in the second wavelength band. The edge of the second color filter CF2 may be disposed on the edge of the first color filter CF1, and the central area of the second color filter CF2 may be disposed on the second light-emitting element OLED2. The third color filter CF3 may be between the edge of the second color filter CF2 and the edge of the first color filter CF1.

Furthermore, as illustrated in FIGS. 24 and 26, distance d6 and d6′ between the first color filters CF1 measured along the cutting line V-V′ in a plan view may vary depending on a position at which the first color filter CF1 is located. For example, the distances d6 and d6′ between the first color filters CF1 may be the diameters of the openings defined by the first color filter CF1 in a plan view. As a result, diffraction patterns formed when external light is reflected by various diameters of the openings defined by the first color filter CF1 may be minimized.

As illustrated in FIG. 25, the widths of the second color filter CF2 measured along the cutting line V-V′ in a plan view may be equal to each other. Also, as illustrated in FIG. 26, the widths of the second color filter CF2 measured along the cutting line VI-VI′ in a plan view may be equal to each other.

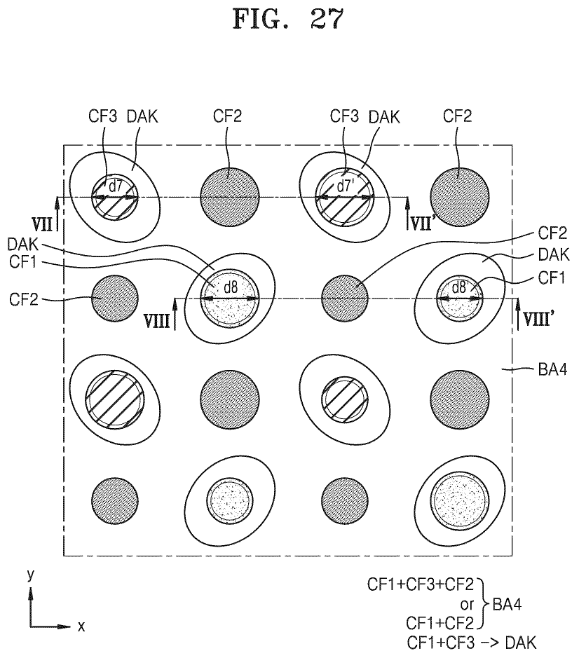

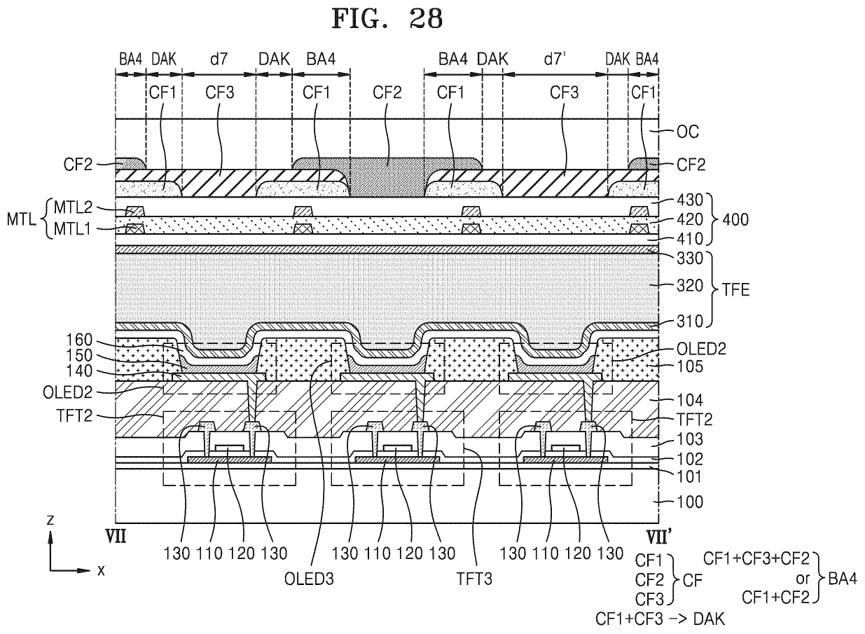

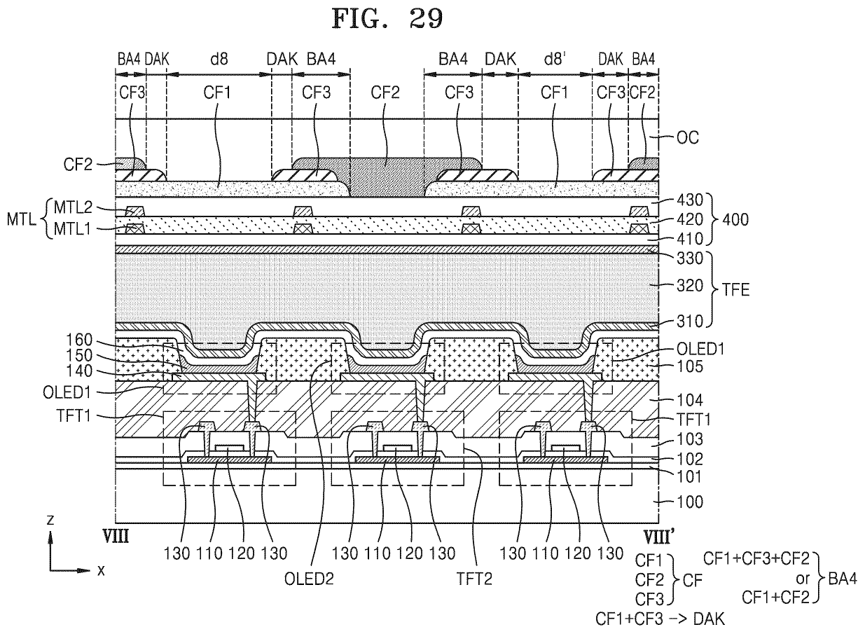

FIG. 27 is a plan view illustrating a portion of a display apparatus, focusing on a color filter layer CF and a light blocking material layer BM, according to another embodiment, FIG. 28 is a cross-sectional view of the display apparatus of FIG. 27 taken along line VII-VII′ of FIG. 27, and FIG. 29 is a cross-sectional view of the display apparatus of FIG. 27 taken along line VIII-VIII′ of FIG. 27.

In the following description of FIGS. 27 to 29, the same or redundant description as provided above may be omitted.

As illustrated in FIGS. 27 to 29, a display apparatus, according to another embodiment, may replace the light blocking material layer BM with the color filter layer CF. As described above, the function of blocking internal light and/or external light may be mainly performed by a first color filter CF1 and a third color filter CF3. Therefore, changing the design of the color filter pattern may be mainly accomplished by changing the size of a second color filter CF2.

For example, as illustrated in FIG. 27, an area where the existing light blocking material layer BM is present may be referred to as a fourth replacement area BA4. As illustrated in FIGS. 28 and 29, the fourth replacement area BA4 may be formed by the overlapping of a first color filter CF1 (e.g., a color filter configured to transmit a blue wavelength band), a third color filter CF3 which is disposed on the first color filter CF1 (e.g., a color filter configured to transmit a red wavelength band), and a second color filter CF2 which is disposed on the third color filter CF3 (e.g., a color filter configured to transmit a green wavelength band). In another embodiment, the fourth replacement area BA4 may be formed by the overlapping of the first color filter CF1 and the second color filter CF2.

For example, as illustrated in FIGS. 27 to 29, an area that overlaps the first color filter CF1 in a plan view among areas where the second color filter CF2 is removed may be an erase area DAK. The erase area DAK may be formed by the overlapping of the first color filter CF1 and the third color filter CF3.

As illustrated in FIG. 28, the edge of the third color filter CF3 may cover the upper surface of the first color filter CF1. As a result, a first touch conductive layer MTL1 and a second touch conductive layer MTL2 may be covered with the first color filter CF1 and the third color filter CF3. As such, at least a portion of external light or internal light may be blocked by the first color filter CF1 and the third color filter CF3.

Also as illustrated in FIG. 28, the second color filter CF2 may be disposed on a second light-emitting element OLED2 which is configured to generate light in a second wavelength band, where the edge of the second color filter CF2 may cover the edge of the third color filter CF3 which is disposed on the first touch conductive layer MTL1 and the second touch conductive layer MTL2.

As illustrated in FIG. 28, distances d7 and d7′ between the first color filters CF1 replacing the light blocking material layer BM may be variously formed. The distance d7 and d7′ between the first color filters CF1 measured along the cutting line VII-VII′ in a plan view may vary depending on a position at which the first color filter CF1 is located. For example, the distances between the first color filters CF1 may be the diameters of the openings defined by the first color filter CF1 in a plan view. As a result, diffraction patterns formed when external light is reflected by various diameters of the openings defined by the first color filter CF1 may be minimized.

Moreover, as illustrated in FIG. 29, the first color filter CF1 may be disposed on a first light-emitting element OLED1 which is configured to generate light in a first wavelength band. In a plan view, the first color filter CF1 may cover the first touch conductive layer MTL1 and the second touch conductive layer MTL2 and may also cover the first light-emitting element OLED1. For example, the edge of the first color filter CF1 may be disposed on the first touch conductive layer MTL1 and the second touch conductive layer MTL2, and the central area of the first color filter CF1 may be disposed on the first light-emitting element OLED1. Additionally, the third color filter CF3 may be disposed on the edge of the first color filter CF1, and the third color filter CF3 may be disposed on the first touch conductive layer MTL1 and the second touch conductive layer MTL2.

As illustrated in FIG. 29, the second color filter CF2 may be disposed on the second light-emitting element OLED2 which is configured to generate light in the second wavelength band. For example, the edge of the second color filter CF2 may be disposed on the edge of the first color filter CF1, and the central area of the second color filter CF2 may be disposed on the second light-emitting element OLED2.

As illustrated in FIG. 29, because distances d8 and d8′ between the third color filter CF3 may be variously formed, the distances d8 and d8′ between the third color filter CF3 measured along the cutting line VIII-VIII′ in a plan view may vary depending on a position at which the third color filter CF3 is located. As a result, diffraction patterns formed by reflection of external light due to the various distances of the third color filters CF3 may be minimized.

According to one or more embodiments, the display apparatus in which diffraction patterns observed on the screen are prevented or minimized may be implemented.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A display apparatus comprising:
a substrate;
a plurality of light-emitting elements disposed on the substrate, where the plurality of light-emitting elements comprise at least a first light-emitting element configured to generate light in a first wavelength band, a second light-emitting element configured to generate light in a second wavelength band, and a third light-emitting element configured to generate light in a third wavelength band;
a pixel defining layer disposed on the substrate and arranged to be on a same layer as the plurality of light-emitting elements, where the pixel defining layer covers an edge of each of the plurality of light-emitting elements;
a light blocking material layer disposed on the pixel defining layer; and
a color filter layer disposed on the plurality of light-emitting elements and arranged to be on a same layer as the light blocking material layer, where the color filter layer comprises a first color filter configured to transmit the light in the first wavelength band, a second color filter configured to transmit the light in the second wavelength band, and a third color filter configured to transmit the light in the third wavelength band, where, in a plan view, the first color filter, the second color filter and the third color filter each have an elliptical shape and do not overlap each other.

2. The display apparatus of claim 1, wherein the first color filter, the second color filter and the third color filter are arranged to be on a same layer.

3. The display apparatus of claim 1, wherein a portion of the light blocking material layer is exposed in an upward direction to be between the first color filter, the second color filter and the third color filter.

4. The display apparatus of claim 3, further comprising an overcoating layer disposed on the color filter layer and the light blocking material layer.

5. The display apparatus of claim 4, wherein a portion of the light blocking material layer is in contact with a lower surface of the overcoating layer.

6. The display apparatus of claim 1, wherein the light blocking material layer comprises a plurality of openings respectively disposed on the plurality of light-emitting elements in a plan view.

7. The display apparatus of claim 6, wherein the plurality of openings comprise a first opening in which the first color filter is arranged, a second opening in which the second color filter is arranged, and a third opening in which the third color filter is arranged.

8. The display apparatus of claim 7, wherein, in a plan view, areas of the first opening, the second opening and the third opening do not match each other.

9. The display apparatus of claim 7, wherein, in a plan view, diameters of the first opening, the second opening and the third opening are different from each other.

10. The display apparatus of claim 7, wherein the first color filter covers an inner surface of the first opening, the second color filter covers an inner surface of the second opening, and the third color filter covers an inner surface of the third opening.

11. The display apparatus of claim 1, wherein a distance between a central area of the first color filter and an upper surface of the substrate is less than a distance between an upper surface of the light blocking material layer and the upper surface of the substrate.

12. The display apparatus of claim 11, wherein a distance between a central area of the second color filter and the upper surface of the substrate is less than the distance between the upper surface of the light blocking material layer and the upper surface of the substrate.

13. The display apparatus of claim 11, wherein a central area of each of the first color filter, the second color filter and the third color filter has a concavely recessed shape.

14. The display apparatus of claim 1, wherein, in a plan view, the first color filter has a first elliptical shape with a first major axis extending in a first direction,
in a plan view, the second color filter has a second elliptical shape with a second major axis extending in a second direction, and
in a plan view, the third color filter has a third elliptical shape with a third major axis extending in a third direction.

15. The display apparatus of claim 14, wherein, in a plan view, the first direction, the second direction and the third direction are different from each other.

16. The display apparatus of claim 14, wherein, in a plan view, an eccentricity of the first elliptical shape, an eccentricity of the second elliptical shape and an eccentricity of the third elliptical shape are different from each other.

17. The display apparatus of claim 14, where, in a plan view, an area of the first elliptical shape, an area of the second elliptical shape and an area of the third elliptical shape are different from each other.

18. The display apparatus of claim 17, wherein, in a plan view, a ratio of the area of the first elliptical shape to the area of the second elliptical shape is about 2:3.

19. The display apparatus of claim 18, wherein an eccentricity of the first elliptical shape and an eccentricity of the second elliptical shape are between about 0.5 and about 0.8.

20. A display apparatus comprising:
a substrate;
a plurality of light-emitting elements disposed on the substrate, where the plurality of light-emitting elements comprises at least a first light-emitting element configured to generate light in a first wavelength band, a second light-emitting element configured to generate light in a second wavelength band, and a third light-emitting element configured to generate light in a third wavelength band;
a pixel defining layer disposed on the substrate and arranged to be on a same layer as the plurality of light-emitting elements, where the pixel defining layer covers an edge of each of the plurality of light-emitting elements;
a touch sensor layer disposed on the plurality of light-emitting elements and the pixel defining layer, where the touch sensor layer comprises a touch conductive layer that overlaps the pixel defining layer in a plan view; and
a color filter layer disposed on the touch sensor layer, where the color filter layer comprises a first color filter configured to transmit the light in the first wavelength band, a second color filter configured to transmit the light in the second wavelength band, and a third color filter configured to transmit the light in the third wavelength band,
where, in a plan view, an edge of the first color filter overlaps the touch conductive layer,
in a plan view, a central area of the first color filter overlaps the first light-emitting element, and
a portion of the second color filter is disposed on the edge of the first color filter, and a remaining portion of the second color filter overlaps the second light-emitting element in a plan view.
